(19) United States
(12) Patent Application Publication
(10) Pub. No.: US 2014/0014036 A1
(43) Pub. Date: Jan. 16, 2014

(54) DEPOSITION PARTICLE EMITTING DEVICE, DEPOSITION PARTICLE EMISSION METHOD, AND DEPOSITION DEVICE

(71) Applicants: Tohru Sonoda, Osaka (JP); Shinichi Kawato, Osaka (JP); Satoshi Inoue, Osaka (JP); Satoshi Hashimoto, Osaka (JP)

(72) Inventors: Tohru Sonoda, Osaka (JP); Shinichi Kawato, Osaka (JP); Satoshi Inoue, Osaka (JP); Satoshi Hashimoto, Osaka (JP)

(73) Assignee: Sharp Kabushiki Kaisha, Osaka (JP)

(21) Appl. No.: 14/007,956

(22) PCT Filed: Mar. 23, 2012
(86) PCT No.: PCT/JP2012/057544

§ 371 Date: Sep. 26, 2013

(51) Int. Cl. H01L 21/02; B65D 85/00

(52) U.S. Cl. CPC H01L 21/02104; B65D 85/70
USPC 118/712; 118/724; 206/525

(57) ABSTRACT

A vapor deposition particle emitting device of the present invention includes: a nozzle section (110) having emission holes (111) from which gaseous vapor deposition particles are emitted out; a heating plate unit (100), provided in the nozzle section (110), which is made up of heating plates (101) each having a surface on which a vapor deposition material remains as a result of adherence of vapor deposition particles to the surface; and a heating device (160) for heating the vapor deposition material, which is thus remaining on the surface of each of the heating plates (101), so that a temperature of the vapor deposition material is not less than a temperature at which to become transformed into gaseous form.

### TECHNICAL FIELD

The present invention relates to (i) a vapor deposition particle emitting device, (ii) a method for emitting vapor deposition particles, and (iii) a vapor deposition device including, as a vapor deposition source, a deposition particle emitting device.

### BACKGROUND ART

Recent years have witnessed practical use of a flat-panel display in various products and fields. This has led to a demand for a flat-panel display that is larger in size, achieves higher image quality, and consumes less power.

Under such circumstances, great attention has been drawn to an organic EL display device that (i) includes an organic electroluminescence (hereinafter abbreviated to “EL”) element which uses EL of an organic material and that (ii) is an all-solid-state flat-panel display which is excellent in, for example, low-voltage driving, high-speed response, and self-emitting.

An organic EL display device includes, for example, (i) a substrate made up of members such as a glass substrate and TFTs (thin film transistors) provided to the glass substrate and (ii) organic EL elements provided on the substrate and connected to the TFTs.

An organic EL element is a light-emitting element capable of high-luminance light emission based on low-voltage direct-current driving, and includes in its structure a first electrode, an organic EL layer, and a second electrode stacked on top of one another in that order, the first electrode being connected to a TFT.

The organic EL layer between the first electrode and the second electrode is an organic layer including a stack of layers such as a hole injection layer, a hole transfer layer, an electron blocking layer, a luminescent layer, a hole blocking layer, an electron transfer layer, and an electron injection layer.

A full-color organic EL display device typically includes organic EL elements of red (R), green (G), and blue (B) as sub-pixels aligned on a substrate. The full-color organic EL display device carries out an image display by, with use of TFTs, selectively causing the organic EL elements to each emit light with a desired luminance.

An organic EL element provided in a light emitting section of such an organic EL display device is typically formed by vapor depositing layers of organic films. In production of an organic EL display device, a luminescent layer is formed in a predetermined pattern for each organic EL element that is a light-emitting element, which luminescent layer is made of an organic luminescent material that emit light of at least red (R), green (G), and blue (B).

Examples of a method for forming the predetermined pattern (of vapor-deposited layers) encompass (i) a vapor deposition method in which a mask called a shadow mask is employed, (ii) an inkjet method, and (iii) a laser transfer method. Among these, a method that is currently the most typical is a vacuum vapor deposition method in which a mask called a shadow mask is employed.

The vacuum vapor deposition method is carried out as follows: (i) a vapor deposition source for vaporizing or sublimating a vapor deposition material is provided inside of a vacuum chamber where reduced pressure can be maintained and then (ii) the vapor deposition material is heated, for example, under highly vacuum conditions so as to be vaporized or sublimated.

Note that, in a case where (i) the vacuum vapor deposition method is used for production of an organic EL display device and (ii) selective vapor deposition is made for luminescent layers, it is necessary to properly guide vapor deposition particles toward a target region on which the vapor deposition particles are to be vapor-deposited. If the vapor deposition particles fail to properly reach the target region, then boundaries of the target region become indefinite. This results in blurring vapor deposition. Under the circumstances, there are technologies (e.g. Patent Literature 1 etc.) proposed for reducing blurring vapor deposition by, for example, providing, between a vapor deposition source inside of a vacuum chamber and a vapor deposition object, a vapor deposition jet controlling section such as a restriction plate for controlling an increase in directivity of a vapor deposition jet (flow of vapor deposition particles).

FIG. 13 is a view schematically illustrating a vapor deposition device that uses a restriction panel differing from that used in the vacuum vapor deposition device disclosed in Patent Literature 1.

According to the vapor deposition device illustrated in FIG. 13, a vapor deposition source unit 1050 is made up of (i) a vapor deposition source 1060, (ii) a control block (equivalent to the vapor deposition jet control section) 1085 including a plurality of control plates 1086, and (iii) a vapor deposition mask 1070 having, therein, stripe-shaped openings 1071 extending in a direction of a Y-axis illustrated in FIG. 13. A film is to be formed on a substrate 1010, which is a vapor deposition object, by moving, in the Y-axis direction, the substrate 1010 while the vapor deposition source unit 1050 is stabilized. Specifically, vapor deposition particles 1091 adhere to a vapor-deposited surface of the substrate 1010 by moving the substrate 1010 in the Y-axis direction while the vapor deposition particles 1091 are emitted from a plurality of vapor deposition source openings 1061 of the vapor deposition source 1060. This forms a plurality of stripe-shaped films extending parallel in the Y-axis direction.

The vapor deposition device illustrated in FIG. 13 is configured so that vapor deposition particles 1091, which have been emitted from the plurality of vapor deposition source openings 1061, pass through the control block 1085 and then through the vapor deposition mask 1070 before reaching the substrate 1010 so that directivity of the vapor deposition particles 1091 can be controlled. This allows the vapor deposition particles 1091 to be properly guided toward a target region on which the vapor deposition particles 1091 are to be vapor-deposited. Therefore, blurring vapor deposition is prevented.

### CITATION LIST

### Patent Literature

Patent Literature 1
Japanese Patent Application Publication, Tokukai, No. 2004-137583 A (Publication Date: May 13, 2004)

### SUMMARY OF INVENTION

### Technical Problem

However, the use of the control block 1085 poses the problem of a low vapor deposition rate. This is because, although part of vapor deposition particles 1091 emitted from the plurality of vapor deposition source openings 1061 passes through the control block 1085 so as to be vapor-deposited, the majority of the vapor deposition particles 1091 are obstructed by the control block 1085 so as to be prevented from being vapor-deposited, and are therefore wasted.

Note that in order to improve the vapor deposition rate, it is an option to increase a heating temperature at which a vapor deposition material is heated in the vapor deposition source 1060. However, there is then a problem that since the vapor deposition material is an organic matter and therefore has low thermal conductivity, an excessive increase in the heating temperature causes the vapor deposition material to be exceedingly heated due to delay in its heat conduction. This causes the vapor deposition material to be pyrolyzed and therefore deteriorated.

The present invention has been made in view of the problems, and it is an object of the present invention to provide a vapor deposition particle emitting device that is capable of improving a vapor deposition rate even though a vapor deposition material is not excessively heated.

### Solution to Problem

A vapor deposition particle emitting device of the present invention includes: an emitting container having emission holes from which gaseous vapor deposition particles are emitted out; an adhered object, provided in the emitting container, to which vapor deposition particles adhere so that a vapor deposition material remains on a surface of the adhered object; and a heating device for heating the vapor deposition material, which is remaining on the surface of the adhered object, so that a temperature of the vapor deposition material is not less than a temperature at which the vapor deposition material becomes transformed into gaseous form.

According to the configuration, the vapor deposition material is in a state of remaining on the surface of the adhered object as a result of adherence of the vapor deposition particles to the surface. This causes heat, which has been applied to the vapor deposition material, to easily flow through the entire vapor deposition material. Therefore, by merely heating the vapor deposition material so that its temperature is not less than a temperature at which to become transformed into gaseous form, it is possible to obtain a large amount of gaseous vapor deposition particles at once. In other words, it is possible to increase a vapor deposition rate.

A larger surface area of the adhered object allows a larger amount of vapor deposition particles to adhere to the surface of the adhered object, and therefore allows a larger amount of vapor deposition material to remain on the surface of the adhered object. This makes it possible to obtain even a larger amount of vapor deposition particles at once, i.e., to further increase the vapor deposition rate.

In addition, since applied heat can easily flow through the entire vapor deposition material as described above, the vapor deposition material remaining on the surface of the adhered object can be sufficiently transformed into gaseous form with the use of heat at a temperature as close as possible to a vaporizing temperature of the vapor deposition material (in a case where the vapor deposition material is in liquid form) or a sublimating temperature of the vapor deposition material (in a case where the vapor deposition material is in solid form). This makes it unnecessary to excessively heat up the vapor deposition material for the purpose of increasing the vapor deposition rate, and therefore makes it possible to prevent the vapor deposition material from deteriorating due to excessive heat.

With the configuration, therefore, it is possible to increase the vapor deposition rate without excessively heating up the vapor deposition material.

A vapor deposition particle emitting device of the present invention includes: a vapor deposition particle generating source for generating gaseous vapor deposition particles by heating a vapor deposition material; an emitting container, connected to the vapor deposition particle generating source, which has emission holes for emitting out gaseous vapor deposition particles; an adhered object, provided in the emitting container, to which vapor deposition particles adhere so that the vapor deposition material remains on a surface of the adhered object; and a surface temperature controlling device for controlling a surface temperature of the adhered object so as to be less or not less than a temperature at which the vapor deposition material becomes transformed into gaseous form.

Note that a temperature, at which gaseous vapor deposition particles are generated from a vapor deposition material, is (i) a vaporizing temperature in a case where the vapor deposition material is in liquid form and (ii) a sublimating temperature in a case where the vapor deposition material is in solid form.

According to the configuration, (i) in a case where the surface temperature controlling device controls the surface temperature of the adhered object so as to be lower than a temperature at which gaseous vapor deposition particles are generated from a vapor deposition material, it is possible to cause the vapor deposition material to remain on the surface of the adhered object by causing the vapor deposition particles to adhere to the surface and (ii) in a case where the surface temperature controlling device controls the surface temperature of the adhered object so as to be not less than the temperature at which gaseous vapor deposition particles are generated from a vapor deposition material, it is possible to cause gaseous vapor deposition particles to be generated from the vapor deposition material remaining on the surface of the adhered object.

According to the configuration, the vapor deposition particle emitting device is thus configured so that (i) a vapor deposition material is made to remain on the surface of the adhered object, which is contained in the emitting container, by causing gaseous vapor deposition particles to adhere to the surface and then (ii) gaseous vapor deposition particles are generated from the vapor deposition material thus remaining on the adhered object. This allows an amount of vapor deposition material, which is to be transformed into gaseous form at once, to be increased without raising a heating temperature as much as is the case in which a vapor deposition material is transformed into gaseous form by being heated in a crucible or the like. That is, a vapor deposition rate can be increased.

### Advantageous Effects of Invention

A vapor deposition particle emitting device of the present invention includes: an emitting container having emission holes from which gaseous vapor deposition particles are emitted out; an adhered object, provided in the emitting container, to which vapor deposition particles adhere so that a vapor deposition material remains on a surface of the adhered object; and a heating device for heating the vapor deposition material, which is remaining on the surface of the adhered object, so that a temperature of the vapor deposition material is not less than a temperature at which the vapor deposition material becomes transformed into gaseous form. This makes it possible to increase a vapor deposition rate without excessively heating up a vapor deposition material.

### BRIEF DESCRIPTION OF DRAWINGS

FIG. 1 is a view schematically illustrating an entire vapor deposition device including a vapor deposition particle emitting device in accordance with Embodiment 1 of the present invention.

FIG. 2 is a view illustrating an example of how heating plates, which are provided inside heating plate unit included in the vapor deposition particle emitting device illustrated in FIG. 1, are arranged.

(a), (b), and (c) of FIG. 3 are views illustrating a principle by which (i) vapor deposition particles adhere to the heating plates illustrated in FIG. 2 and then (ii) a vapor deposition material becomes transformed into gaseous form.

(a), (b), and (c) of FIG. 4 are views each illustrating an example of an adhered object, other than the heating plates illustrated in FIG. 2, to which vapor deposition particles are to adhere.

FIG. 5 is a view schematically illustrating a vapor deposition processing system that includes the vapor deposition particle emitting device illustrated in FIG. 1.

FIG. 6 is a cross-sectional view schematically illustrating a full-color (R, G, B) organic EL display device.

FIG. 7 is a cross-sectional view illustrating a TFT substrate included in an organic EL display device.

FIG. 8 is a flow chart illustrating, in order of steps, a process of producing an organic EL display device.

FIG. 9 is a view schematically illustrating a vapor deposition processing system for comparison with the vapor deposition processing system illustrated in FIG. 5.

FIG. 10 is a view schematically illustrating an entire vapor deposition device that includes a vapor deposition particle emitting device in accordance with Embodiment 2 of the present invention.

FIG. 11 is a view schematically illustrating a vapor deposition material filling device in which vapor deposition particles are to adhere to a heating plate unit for use in the vapor deposition particle emitting device illustrated in FIG. 10.

FIG. 12 is a view schematically illustrating an entire vapor deposition device that includes a vapor deposition particle emitting device in accordance with Embodiment 3 of the present invention.

FIG. 13 is a view schematically illustrating a vacuum vapor deposition device that includes a vapor deposition jet controlling section.

### DESCRIPTION OF EMBODIMENTS

### Embodiment 1

The following description will discuss Embodiment 1 of the present invention.

<Entire Configuration of Vapor Deposition Device>

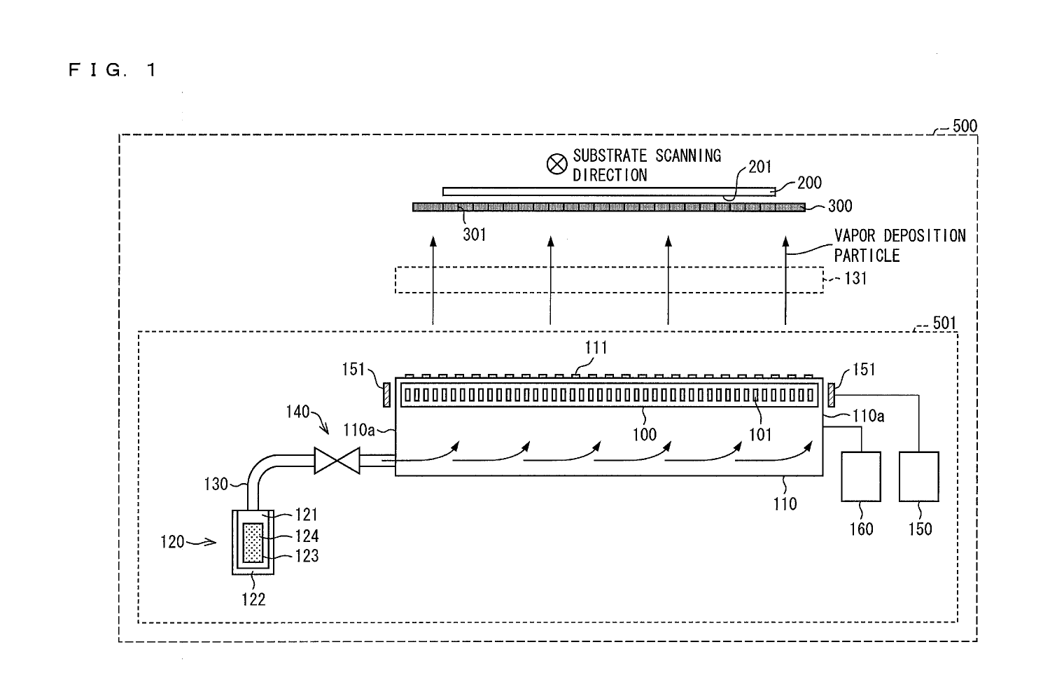

FIG. 1 is a view schematically illustrating an entire vapor deposition device including a vapor deposition particle emitting device in accordance with Embodiment 1 of the present invention.

As illustrated in FIG. 1, the vapor deposition particle emitting device is configured so that a vacuum chamber vacuum chamber 500 includes, as a vapor deposition source, a vapor deposition particle emitting device 501.

The vapor deposition particle emitting device 501 includes (i) a nozzle section (emitting container) 110 having a plurality of emission holes 111 and (ii) a vapor deposition particle generating section (vapor deposition particle generation source) 120.

The vapor deposition particle generating section 120 includes (i) a container 121, (ii) a heater (heating member) 122 provided outside the container 122, and (iii) a crucible 123 provided inside the container 121. The vapor deposition particle generating section 120 generates gaseous vapor deposition particles, by vaporizing (in a case of a liquid vapor deposition material) or sublimating (in a case of a solid vapor deposition material) a vapor deposition material 124 through heating the vapor deposition material 124 provided inside the crucible 123.

The nozzle section 110 and the vapor deposition particle generating section 120 are connected to each other, via an introduction tube (connecting channel) 130. This causes vapor deposition particles, which have been generated in the vapor deposition particle generating section 120, to be introduced into the nozzle section 110 via the introduction tube 130. A valve 140 is further provided, at the introduction tube 130, so as to be closed or opened as needed. Specifically, in a case where the valve 140 is opened, the vapor deposition particles are introduced from the vapor deposition particle generating section 120 into the nozzle section 110, via the introduction tube 130. In a case where the valve 140 is closed, the vapor deposition particles are not introduced from the vapor deposition particle generating section 120 into the nozzle section 110.

The nozzle section 110 includes a heating plate unit 100 made up of a plurality of heating plates (adhered objects) 101, each having a surface onto which vapor deposition particles can adhere. The heating plate unit 100 and the heating plates 101 will be described later in detail.

The vapor deposition particle emitting device 501 further includes (i) a cooling device 150 for externally cooling the nozzle section 110 and (ii) a heating device 160 for externally heating the nozzle section 110.

The cooling device 150 cools a surface of each of the heating plates 101 down to a temperature lower than a temperature at which a vapor deposition material 124 is transformed into gaseous form. The heating device 160 heats the surface of each of the heating plates 101 up to a temperature not less than the temperature at which the vapor deposition material 124 is transformed into gaseous form.

The cooling device 150 includes a heat exchange member 151, which takes the heat from the nozzle section 110 by coming into contact with a housing outer circumferential surface 110a of the nozzle section 110. The heat exchange member 151 is provided so as to be attachable to or detachable from the housing outer circumferential surface 110a. Specifically, the cooling device 150 is configured so that (i) the heat exchange member 151 comes into contact with the housing outer circumferential surface 110a when the nozzle section 110 needs to be cooled down and (ii) the heat exchange member 151 is detached from the housing outer circumferential surface 110a when the nozzle section 110 no longer needs to be cooled down (e.g. when a heating process by the heating device 160 is to be initiated etc.). Note that the heat exchange member 151 is driven by a driving mechanism (not illustrated).

The heating device 160 is configured to heat up the inside of the nozzle section 110 by driving a heating member (not illustrated), such as a heater, which is provided inside the nozzle section 110. Specifically, the heating device 160 (i) drives, when the nozzle section 110 needs to be heated, the heating member so as to heat up the inside of the nozzle section 110 and (ii) suspends driving of the heating member when the inside of the nozzle section 110 does not need to be heated (e.g. when a cooling process is to be initiated by the cooling device 150).

The surface temperatures of the heating plates 101 are thus controlled to be (i) less than the temperature, at which the vapor deposition material 124 is transformed into gaseous form, by the cooling device 150 cooling down the nozzle section 110 and (ii) not less than the temperature by the heating device 160 heating up the nozzle section 110. That is, the cooling device 150 and the heating device 160 collectively function as a surface temperature controlling device for controlling the surface temperatures of the heating plates 101 which make up the heating plate unit 100 that is inside the nozzle section 110.

Note that the phrase “temperature at which gaseous vapor deposition particles are generated from a vapor deposition material 124” herein means (i) a vaporizing temperature of a vapor deposition material 124 (in the case where a vapor deposition material is in liquid form) or (ii) a sublimating temperature of a vapor deposition material 124 (in the case where a vapor deposition material is in solid form).

In a case where (i) gaseous vapor deposition particles, which have been introduced into the nozzle section 110, are yet to adhere to the surfaces of the heating plates 101 and (ii) the cooling device 150 cools the surfaces of the heating plates 101 down to the vaporizing/sublimating temperature of the vapor deposition material 124, the gaseous vapor deposition particles adhere to the surfaces of the heating plates 101. This causes a vapor deposition material to remain on the surfaces of the heating plates 101.

Each of heating plates 101, on which a vapor deposition material remains as a result of adhesion of vapor deposition particles, is hereinafter referred to as a “vapor deposition particle adhered body.”

In a case where (i) vapor deposition particles are adhering to the surfaces of the heating plates 101 and (ii) the nozzle section 110 is heated up to a temperature not less than the vaporizing/sublimating temperature of the vapor deposition material 124, a vapor deposition material remaining on the heating plates 101 is transformed into gaseous form.

At an upper part of the vacuum chamber 500, a vapor deposition mask 300 and a film formation substrate (vapor-deposition object) 200 are each provided so as to face the nozzle section 110 of the vapor deposition particle emitting device 501. Note that there is a space between the vapor deposition mask 300 and the film formation substrate 200. Note also that a relative physical relationship is maintained between of the vapor deposition mask 300 to the vapor deposition particle emitting device 501. A vapor deposition process is therefore made by (i) stabilizing either (a) the vapor deposition mask 300 and the vapor deposition particle emitting device 501 or (b) the vapor-deposited substrate 200 and (ii) moving the other in a direction in which the film formation substrate 200 is to be scanned.

In the vacuum chamber 500, a vacuum pump (not illustrated) and an exhaust opening (not illustrated) are provided. The vacuum pump evacuates air from the vacuum chamber 500, via the exhaust, so that a vacuum is maintained in the vacuum chamber 500 during vapor deposition.

A sufficient mean free path of vapor deposition particles can be obtained in a case where the degree of vacuum is more than 1.0×10⁻³ Pa. Note that, in a case where the degree of vacuum is less than 1.0×10⁻³ Pa, the vapor deposition particles are scattered because the mean free path becomes short. This causes (i) a reduction in efficiency at which the vapor deposition particles can reach the film formation substrate 200 and (ii) a reduction in collimated components of a vapor deposition jet.

In view of the circumstances, the vacuum chamber 500 is set to have a degree of vacuum of at least 1.0×10⁻⁴ Pa by the vacuum pump.

In addition, there is provided, as needed, a restriction plate 131 for restricting the flow of vapor deposition particles (vapor deposition jet), between (i) the nozzle section 110 of the vapor deposition particle emitting device 501 and (ii) the vapor deposition mask 300. Like a case of selective vapor deposition of luminescent layers (that make up an organic EL layer of an organic EL element), such a restriction plate 131 is to be provided for reducing the occurrence of a vapor deposition blur (e.g. blurs at both lateral edges of a strip-shaped film formed etc.) that occurs due to scattering of vapor deposition particles.

According to the vapor deposition device configured as such, gaseous vapor deposition particles are generated by, with the use of the heater (heating section) 122 provided in the vapor deposition particle generating section 120, heating a vapor deposition material 124 so as to vaporize (in a case of a liquid vapor deposition material) or sublimate (in a case of a solid vapor deposition material) the vapor deposition material 124.

The vapor deposition particles generated in the vapor deposition particle generating section 120 (i) are directed, through the introduction tube 130 which is connected to the vapor deposition particle generating section 120, toward the nozzle section 110 that is being cooled down by the cooling device 150 and then (ii) adhere onto the surfaces of the heating plates 101. Subsequently, the heating device 160 heats up the inside of the nozzle section 110, so that the vapor deposition material remaining on the surfaces of the heating plates 101 is transformed into gaseous form. Then, the vapor deposition particles, which have been thus transformed into gaseous form, are mixed together in the nozzle section 110, and are finally emitted, toward the film formation substrate 200, from emission holes 111 which are arranged in line.

The vapor deposition particles, which have been thus emitted from the vapor deposition particle emitting device 501, adhere to the film formation substrate 200 via the vapor deposition mask 300. This forms a vapor deposition film on a surface of the film formation substrate 200. In so doing, the vapor deposition film is formed in a pattern since the vapor deposition particles adhere to the film formation substrate 200 via the vapor deposition mask 300.

The vapor deposition mask 300 has openings (through holes) 301 each of which has a desired shape and which are provided at desired locations. This allows only vapor deposition particles, which have passed through the openings 301, to reach the film formation substrate 200. The vapor deposition film is thus formed in a pattern. In a case where patterns are to be formed in respective pixels (such as when a luminescent layer is to be formed), a mask (fine mask), having openings 301 for the respective pixels, is employed. In a case where the vapor deposition particles are to be vapor-deposited on the entire display region (such as when a hole transfer layer or the like is to be formed), a mask (open mask), having an opening for the entire display region, is employed.

Note that Embodiment 1 discusses an example in which the vapor deposition mask 300 (i) is smaller in size than a film formation region of the film formation substrate 200 and (ii) is provided so as to be away from a film formation surface 201 of the film formation substrate 200.

Note, however, that Embodiment 1 is not limited to this. Alternatively, the vapor deposition mask 300 can (i) be tightly fixed to the film formation substrate 200 with the use of fixing means (not illustrated) and/or (ii) have a size corresponding to that of the film formation region of the film formation substrate 200 (e.g., a size identical to that of the film formation region when viewed from above).

In a case where a vapor deposition film is formed, in a solid pattern, on the film formation substrate 200, it is an option to omit the vapor deposition mask 300.

The vapor deposition mask 300 can be selectively provided. For example, the vapor deposition mask 300 may or may not be one of the built-in members that constitute the vapor deposition device.

The following description will discuss a principle under which a vapor deposition rate of the vapor deposition device configured as described above is increased.

<Details of Heating Plate Unit 100>

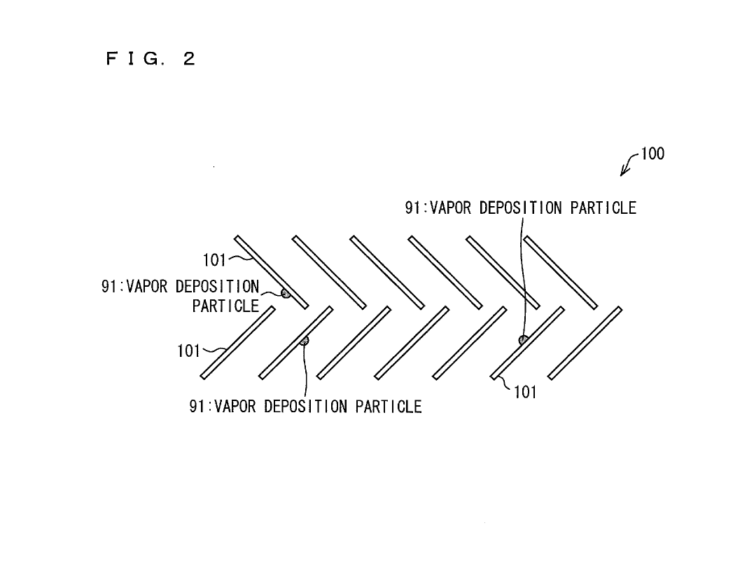

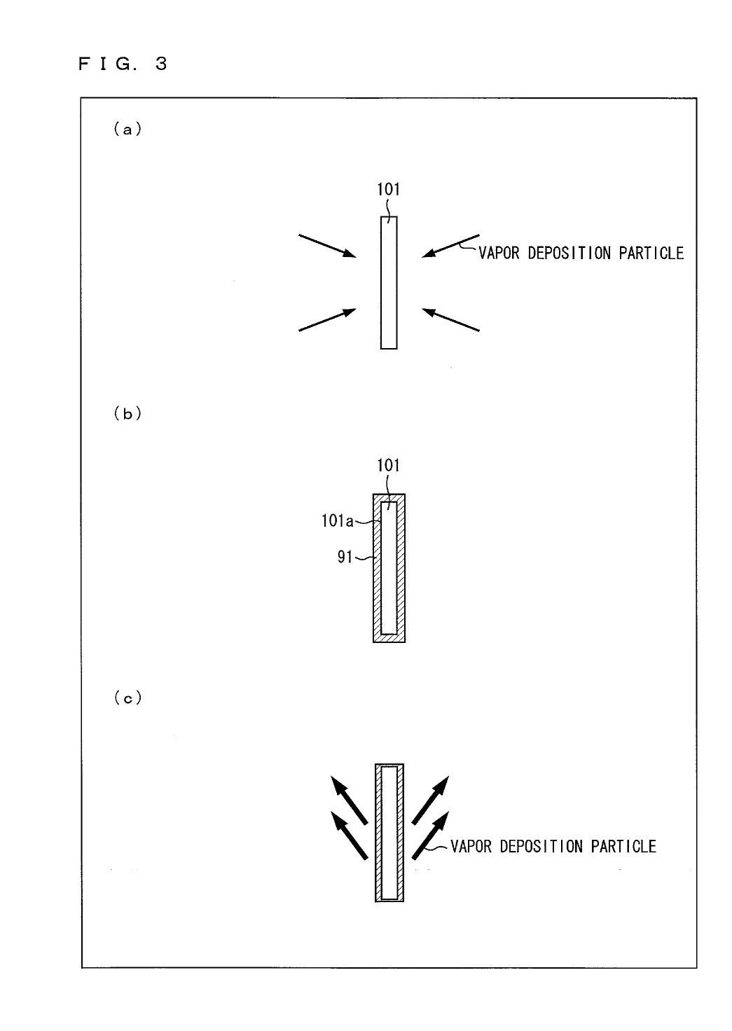

FIG. 2 is a view illustrating an example of how the heating plates 101 are arranged in the heating plate unit 100.

According to the heating plate unit 100, the plurality of the heating plates 101 are juxtaposed (see FIG. 2). Since the heating plates 101 are thus juxtaposed, the surfaces of the respective heating plates 101 are kept apart without being in contact with one another. This makes it possible to obtain a large surface area of the heating plates 101, and therefore allows an increase in e number of vapor deposition particles 91 which are to adhere to the surfaces of the heating plates 101. In addition, by arranging the heating plates 101 as illustrated in FIG. 2, it is made possible to eliminate, in the nozzle section 110, any space that allows, therethrough, a linear flow that reaches the emission holes 111. This causes vapor deposition particles, which have been introduced from the vapor deposition particle generating section 120 into the nozzle section 110 via the introduction tube 130, to be prevented from being emitted out from the vapor deposition particle emitting device 501 via the emission holes 111 without being in contact with the respective surfaces 101a of the heating plates 101. In other words, the vapor deposition particles 91 are likely to adhere to the surfaces 101a.

(a), (b), and (c) of FIG. 3 are views describing a process in which (i) vapor deposition particles adhere to the heating plates 101, (ii) a vapor deposition material remains on the heating plates 101, and (iii) the vapor deposition material is transformed into gaseous form, respectively.

First, gaseous vapor deposition particles adhere to the surfaces 101a of the heating plates 101 (see (a) of FIG. 3). Then, vapor deposition particles 91 remain almost all over the surfaces 101a (see (b) of FIG. 3). Note here that, as illustrated in FIG. 1, temperatures of the respective surfaces 101a are each set so as to be lower than that at which a vapor deposition material 124 is transformed into gaseous form by the cooling device 150 cooling down the nozzle section 110. In other words, the temperatures of the surfaces 101a are each set to be lower than a vaporizing/sublimating temperature of the vapor deposition material 124. This causes the gaseous vapor deposition particles to adhere to the surfaces 101a so as to remain, as a vapor deposition material, on the surfaces 101a.

Note here that the vapor deposition particles also adhere to inner surface walls of the nozzle section 110 in the vicinity of the heating plate unit 100. Note, however, that the vapor deposition particles do not adhere to inner surface walls of the nozzle section 110 in the vicinity of the introduction tube 130. This is because such inner surface walls are not cooled down. In other words, the introduction tube 130 is configured not to clog up.

Note that, during adhesion of vapor deposition particles to the heating plates 101, it is merely necessary to cause the vapor deposition particles to adhere to the surfaces 101a. Hence, there is no need to increase the vapor deposition rate at which the vapor deposition particles, generated in the vapor deposition particle generating section 120, are vapor-deposited on the surfaces 101a of the nozzle section 110.

In a case where the heating plates 101 are heated up while the vapor deposition particles 91 are remaining on the surfaces 101a (see (b) of FIG. 3), the vapor deposition particles 91 are emitted out of the heating plates 101 (see (c) of FIG. 3).

At this point, the temperatures of the surfaces 101a of the heating plates 101 are set to be not lower than a temperature, at which gaseous vapor deposition particles are generated from the vapor deposition material 124, in a case where the heating device 160 heats up the nozzle section 110. That is, the temperatures of the surfaces 101a are set to be not lower than a vaporizing/sublimating temperature of the vapor deposition material 124. This causes the vapor deposition particles 91 remaining on the surfaces 101a to be transformed back into gaseous form, so as to be emitted out of the heating plates 101.

Note that, since the vapor deposition particles 91 are merely adhering to the surfaces 101a, the heat applied to the heating plates 101 is readily conducted to the vapor deposition particles 91. This causes the temperature of the surfaces 101a to be substantially equal to that of the vapor deposition particles 91 remaining on the surfaces 101a. It is therefore possible to cause high-density vapor deposition particles to be emitted out, by heating up the heating plates 101 so that the vapor deposition particles 91 is heated up to at least the temperature at which gaseous vapor deposition particles are generated from the vapor deposition material 124. This results in an increase in the vapor deposition rate of the vapor deposition particles which are emitted out of the heating plates 101.

It is therefore possible to emit, via the emission holes 111, vapor deposition particles at a high vapor deposition rate, by (i) temporarily causing gaseous vapor deposition particles to adhere to the surfaces 101a of the heating plates 101 and then (ii) heating up the heating plates 101, while using the heating plate unit 100.

<Examples of Adhered Object Other than Heating Plate>

The internal configuration of the heating plate unit 100 is not limited to that illustrated in FIG. 2, that is, the configuration in which the plurality of heating plates 101 are juxtaposed. In fact, the internal configuration of the heating plate unit 100 can be changed in various ways, and the greater surface area of the heating plates 101, the more preferable.

(a) through (c) of FIG. 4 are views each illustrating an example, other than the heating plate, of adhered objects each having surfaces to which vapor deposition particles can adhere.

Examples of the adhered objects encompass (i) fin-shaped members as illustrated in (a) of FIG. 4, (ii) a mesh-like member as illustrated in (b) of FIG. 4, (iii) a member having a fractal surface as illustrated in (c) of FIG. 4, and (iv) a sponge-like member (not illustrated).

Note that, in regard to the “fractal surface” illustrated in (c) of FIG. 4, the term “fractal” indicates a geometric concept of a self-similar form in which each part and the entire part share similar shapes. It is possible to obtain a large surface area by designing a surface having such a form.

Note also that, although (a) through (c) of FIG. 4 are each illustrated two-dimensionally, it is preferable, needless to say, if the above described forms are three-dimensionally structured.

As described above, it is preferable that (i) adhered objects making up the heating plate unit 100 each have a form that provide the largest surface area possible and (ii) a material with a high thermal conduction rate is used for the adhered objects, examples of such a material encompass metals such as titanium, tungsten, and stainless steel.

<Vapor Deposition Processing System>

The following description will discuss a vapor deposition processing system for which the vapor deposition device configured as described above is used.

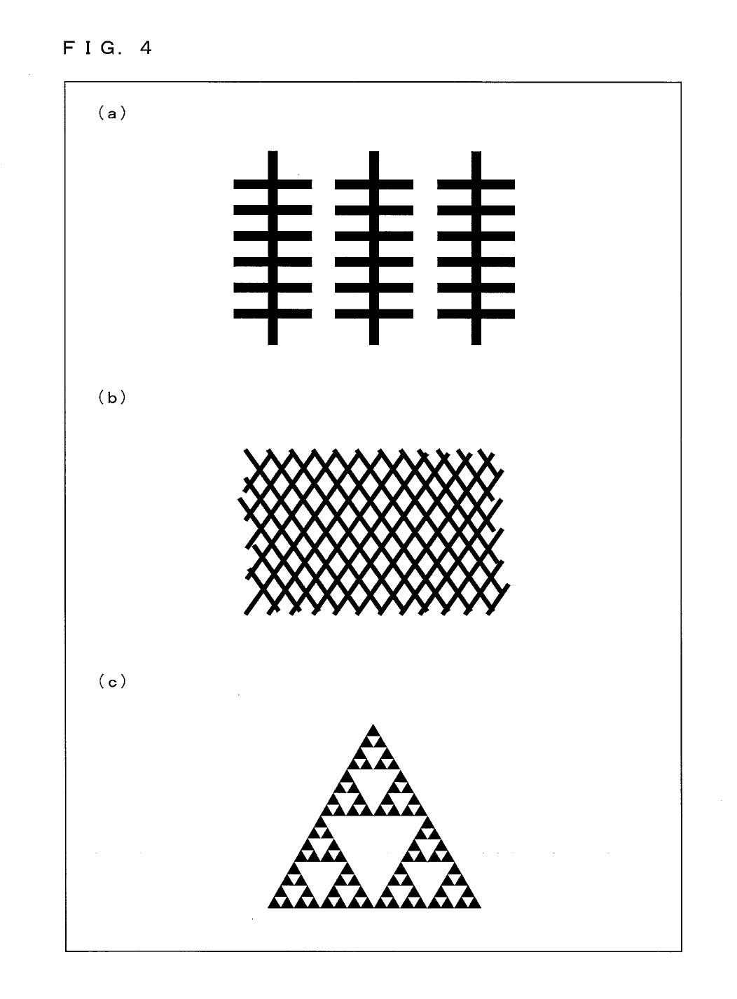

FIG. 5 is a view schematically illustrating a vapor deposition processing system in accordance with Embodiment 1.

According to Embodiment 1, a scanning vapor deposition is made by (i) moving (scanning) the film formation substrate 200 upwards (in a direction perpendicular to a direction in which the emission holes 111 are arranged in line) while vapor deposition particle emitting devices 501 and the vapor deposition mask are fixed or (ii) moving the vapor deposition particle emitting devices 501 upwards/downwards while the film formation substrate 200 is fixed.

As illustrated in FIG. 5, the vapor deposition processing system includes six lines of vapor deposition particle emitting devices 501 juxtaposed in a direction in which relative scanning of the film formation substrate 200 is to be carried out. One of the six lines of vapor deposition particle emitting devices 501 is integrated with a vapor deposition mask 300 so as to make up a vapor deposition source unit 600. FIG. 5 shows that (i) only the vapor deposition particle emitting device 501, which is a part of the vapor deposition source unit 600, is in a state in which to emit vapor deposition particles (vapor depositing state) and (ii) the remaining five vapor deposition particle emitting devices 501 are each in a state in which not to emit vapor deposition particles (non-vapor depositing state).

Note that each of the vapor deposition particle emitting devices 501 is provided with a cooling device 150. A heat exchange member 151 of the cooling device 150 is divided into four blocks which are provided along housing outer circumferential surfaces 110a of a nozzle section 110. The heat exchange member 151 made up of these four blocks is driven by a drive circuit (not illustrated) so that the heat exchange member 151 is (i) detached from the housing outer circumferential surfaces 110a during vapor deposition (while the nozzle section 110 is being heated by the heating device 150) and (ii) closely attached to the housing outer circumferential surfaces 110a during non-vapor deposition (while the nozzle section 110 is being cooled by the cooling device).

According to FIG. 5, (i) a first vapor deposition particle emitting device 501, which is a part of the vapor deposition source unit 600, is in a vapor depositing state and (ii) the remaining five vapor deposition particle emitting devices 501 are each in a non-vapor depositing state. In other words, (I) the first vapor deposition particle emitting device 501 is in a state in which four blocks of a heat exchange member 151 are all detached from respective housing outer circumferential surfaces 110a of a nozzle section 110 and (II) the remaining five vapor deposition particle emitting devices 501 are each in a state in which four blocks of a heat exchange member 151 are all closely attached to respective housing outer circumferential surfaces 110a of a nozzle section 110.

According to Embodiment 1, it is thus only a vapor deposition particle emitting device 501 of a vapor deposition source unit 600 that actually makes vapor deposition on the film formation substrate 200. That is, only one vapor deposition particle emitting device 501 of all the six vapor deposition particle emitting devices 501 emits vapor deposition particles via emission holes 111 of its nozzle section 110 (see FIG. 5).

Note that each of the remaining five vapor deposition particle emitting devices 501, by which no vapor deposition is made, carries out process in which vapor deposition particles adhere to adhered objects in a nozzle section 110. Therefore, in a case where any given vapor deposition particle emitting device 501, making a vapor deposition, runs out of vapor deposition particles to emit, another vapor deposition particle emitting device 501, next in order, is designated as a vapor deposition source unit 600 so as to make a vapor deposition.

According to the vapor deposition source unit 600, a relative physical relationship is maintained between the vapor deposition particle emitting device 501 and the vapor deposition mask 300. As illustrated in FIG. 5, the film formation substrate 200 moves, in one direction (the direction indicated by an arrow in FIG. 5) at constant speed, on an opposite side of the vapor deposition particle emitting device 501 with respect to the vapor deposition mask 300. The vapor deposition particle emitting device 501 has, on its top surface, emission holes 111 each of which emits vapor deposition particles. The vapor deposition mask 300 has openings 301 (mask openings; assigned reference numeral 301 in FIG. 1). The vapor deposition particles emitted from the emission holes 111 pass through the mask openings and then adhere to the film formation substrate 200.

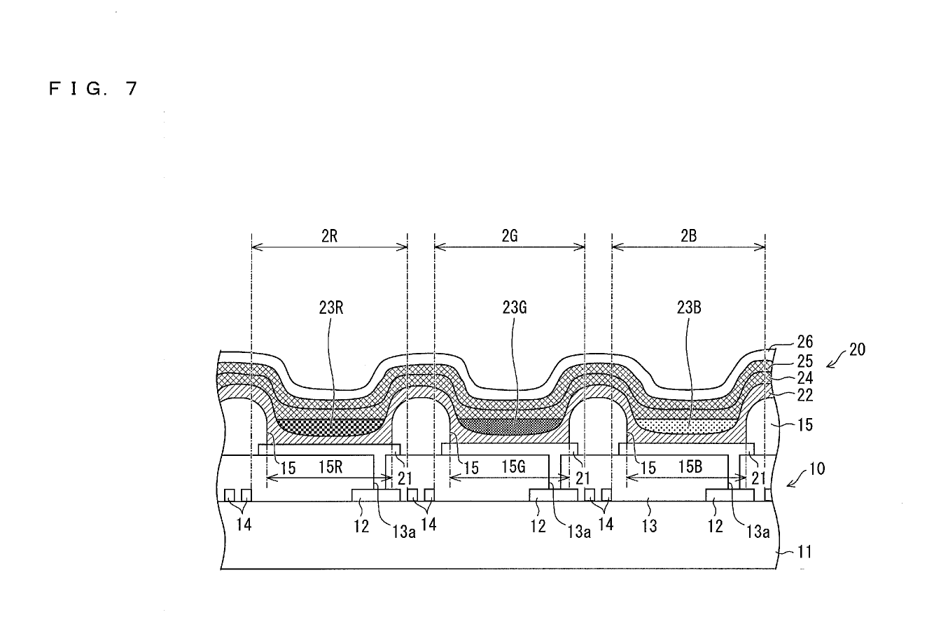

With the above vapor deposition processing system, it is possible to make a selective vapor deposition on each of the luminescent layers 23R, 23G, and 23B, of which an organic EL layer (see FIG. 7) is made up, by repeating vapor deposition on each of luminescent layers 23R, 23G, and 23B.

An organic EL display device to be produced with the use of the vapor deposition device and a method for producing the organic EL display device will be described below.

<Overall Configuration of Organic EL Display Device>

The following description will discuss an overall configuration of the organic EL display device.

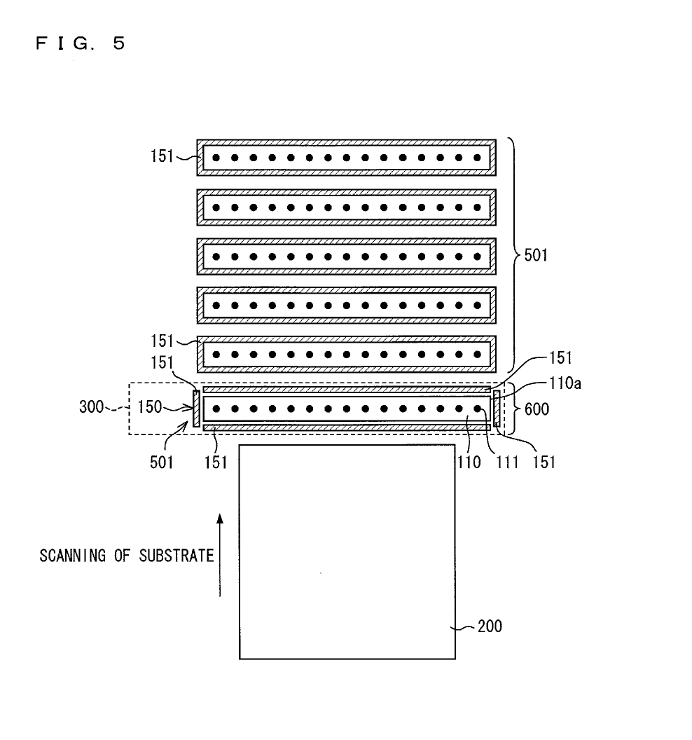

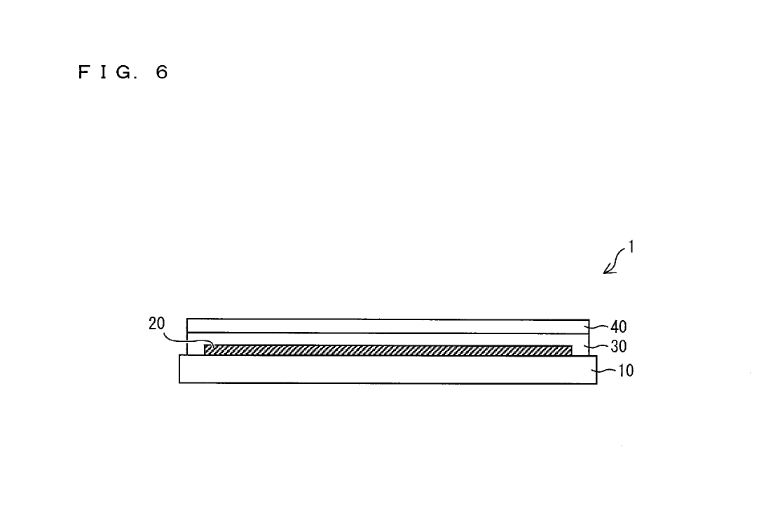

FIG. 6 is a cross-sectional view schematically illustrating a configuration of an RGB full-color organic EL display device 1.

As illustrated in FIG. 6, the organic EL display device 1 to be produced in Embodiment 1 includes (i) a TFT substrate 10 on which TFTs 12 (see FIG. 7) are provided, (ii) organic EL elements 20 connected to the respective TFTs 12, (iii) an adhesive layer 30, (iv) and a sealing substrate 40, which are stacked in this order.

The organic EL elements 20, which are stacked on the TFT substrate 10, are sealed in between a pair of substrates (i.e., the TFT substrate 10 and the sealing substrate 40) by combining together, with the use of the adhesive layer 30, (i) the TFT substrate 10 and (ii) the sealing substrate 40 (see FIG. 6).

Since the organic EL display device 1 is thus configured so that the organic EL element 20 are sealed in between the TFT substrate 10 and the sealing substrate 40, oxygen and moisture are prevented from entering into the organic EL elements 20.

The following description will discuss, in detail, configurations of the TFT substrate 10 and the organic EL elements 20 in the organic EL display device 1.

<Configuration of TFT Substrate 10>

FIG. 7 is a cross-sectional view schematically illustrating how the organic EL elements 20 are configured which constitute a display section of the organic EL display device 1.

The TFT substrate 10 is configured so that TFTs 12 (switching element), wires 14, an interlayer insulating film 13, edge covers 15, and the like are provided on a transparent insulating substrate 11 such as a glass substrate (see FIG. 7).

The organic EL display device 1 is a full-color active matrix organic EL display device, in which pixels 2R, 2G, and 2B are provided on the insulating substrate 11 in a matrix manner. Each of the pixels 2R, 2G, and 2B is constituted by a corresponding one of organic EL elements 20 for red (R), green (G), and blue (B) in a corresponding area surrounded by corresponding wires 14.

The TFTs 12 are provided for the respective pixels 2R, 2G, and 2B. Note that, since each of the TFTs has a conventionally known configuration, layers in each of the TFTs 12 are not illustrated and their descriptions are omitted.

The interlayer insulating film 13 is stacked all over the insulating substrate 11 so as to cover the TFTs 12 and the wires 14.

There are provided on the interlayer insulating film 13 first electrodes 21 of the organic EL elements 20.

The interlayer insulating film 13 has contact holes 13a for electrically connecting the first electrodes 21 of the organic EL elements 20 to the TFTs 12. This causes the TFTs 12 to be electrically connected to the organic EL elements 20 via the respective contact holes 13a.

Each of the edge covers 15 serves as an insulating layer for preventing a corresponding one of the first electrodes 21 from short-circuiting with a corresponding second electrode 26 in a corresponding one of the organic EL elements 20 due to, for example, (i) a reduction in thickness of the organic EL layer in an end part of the corresponding one of the first electrodes 21 and/or (ii) an electric field concentration.

The edge covers 15 are formed on the interlayer insulating film 13 so as to cover end parts of the first electrodes 21.

The first electrodes 21 are exposed in areas which are not covered with the edge covers 15 (see FIG. 7). The areas in which the first electrodes 21 are exposed serve as light-emitting sections in the respective pixels 2R, 2G, and 2B.

In other words, the pixels 2R, 2G, and 2B are isolated from one another by the insulating edge covers 15. The edge covers 15 thus function as element isolation films as well.

<Method of Producing TFT Substrate 10>

The insulating substrate 11 can be made of a material such as non-alkali glass or plastic. In Embodiment 1, non-alkali glass having a board thickness of 0.7 mm is used.

A known photosensitive resin can be employed as each of the interlayer insulating film 13 and the edge covers 15. Examples of such a known photosensitive resin encompass an acrylic resin and a polyimide resin.

Each of the TFTs 12 is produced by a known method. Note that Embodiment 1 is exemplified by the active matrix organic EL display device 1 in which the TFTs 12 are provided for the respective pixels 2R, 2G, and 2B, as above described.

Note, however, that Embodiment 1 is not limited to this, and the present invention is applicable to a method of producing a passive matrix organic EL display device in which no TFT is provided.

<Configuration of Organic EL Element 20>

The organic EL element 20 is a light-emitting element capable of high-luminance light emission and is subjected to low-voltage direct-current driving. The organic EL element 20 is configured so that the first electrode 21, the organic EL layer, and the second electrode 26 are stacked in this order.

The first electrode 21 has a function of injecting (supplying) positive holes into the organic EL layer. The first electrodes 21 are, as described above, connected to the TFTs 12 via the respective contact holes 13a.

Each organic EL layer is provided between a corresponding first electrode 21 and the second electrode 26. Specifically, for example, (i) a hole injection layer/hole transfer layer 22, (ii) a corresponding one of luminescent layers 23R, 23G, and 23B, (iii) an electron transfer layer 24, and (iv) an electron injection layer 25, are formed in this order from the corresponding first electrode 21 side (see FIG. 7).

Note that the organic EL layer can, as needed, further include a carrier blocking layer (not illustrated) for blocking flows of carriers such as positive holes and electrons. A single layer can have a plurality of functions. For example, it is possible to provide a single layer that serves as both a hole injection layer and a hole transfer layer.

According to the above stacking order, the first electrode 21 serves as an anode and the second electrode 26 serves as a cathode. The stacking order of the organic EL layer is reversed in a case where the first electrode 21 serves as a cathode and the second electrode 26 serves as an anode.

The hole injection layer has a function of increasing efficiency in injecting positive holes from the first electrode 21 into the organic EL layer. The hole transfer layer has a function of increasing efficiency in transferring positive holes to the luminescent layers 23R, 23G, and 23B. The hole injection layer/hole transfer layer 22 is uniformly formed all over the display area of the TFT substrate 10 as to cover the first electrode 21 and the edge cover 15.

Embodiment 1 has described a case where the single hole injection layer/hole transfer layer 22, that functions as both a hole injection layer and a hole transfer layer, is employed as the hole injection layer and the hole transfer layer. Embodiment 1 is, however, not limited to such. Alternatively, a hole injection layer and a hole transfer layer can be independently provided.

There are provided on the hole injection layer/hole transfer layer 22 the luminescent layers 23R, 23G, and 23B for the respective pixels 2R, 2G, and 2B.

The luminescent layers 23R, 23G, and 23B are each having a function of emitting light by recombining (i) positive holes injected from a first electrode 21 side with (ii) electrons injected from a second electrode 26 side. The luminescent layers 23R, 23G, and 23B are each made of a material, having high light emission efficiency, such as a low-molecular fluorescent pigment and a metal complex.

The electron transfer layer 24 is a layer that has a function of increasing efficiency in transferring electrons to the luminescent layers 23R, 23G, and 23B. The electron injection layer 25 is a layer that has a function of increasing efficiency in injecting electrons from the second electrode 26 into the organic EL layer.

The electron transfer layer 24 is uniformly provided on the luminescent layers 23R, 23G, and 23B and the hole injection layer/hole transfer layer 22 and all over the entire display area of the TFT substrate 10. This causes the electron transfer layer 24 to cover the luminescent layers 23R, 23G, and 23B and the hole injection layer/hole transfer layer 22.

The electron injection layer 25 is uniformly provided all over the entire display area of the TFT substrate 10 on the electron transfer layer 24 so as to cover the electron transfer layer.

Note that the electron transfer layer 24 and the electron injection layer 25 can be provided (i) independently as described above. Alternatively, a single layer can be provided in which an electron transfer layer 24 and an electron injection layer 25 are integrated with each other. In other words, the organic EL display device 1 can include an electron transfer layer/electron injection layer, instead of the electron transfer layer 24 and the electron injection layer 25.

The second electrode 26 has a function of injecting electrons into the organic EL layer including the above organic layers. The second electrode 26 is uniformly provided all over the entire display area of the TFT substrate 10 on the electron injection layer 25 so as to cover the electron injection layer 25.

The organic layers, other than the luminescent layers 23R, 23G, and 23B, are not essential for the organic EL layer, and can therefore be included as appropriate in accordance with a required property of the organic EL element 20.

A single layer can have a plurality of functions, as with the hole injection layer/hole transfer layer 22 or the electron transfer layer/electron injection layer.

The organic EL layer can further include a carrier blocking layer according to need. The organic EL layer can, for example, further include, as a carrier blocking layer, a hole blocking layer between (i) the electron transfer layer 24 and (ii) the luminescent layers 23R, 23G, and 23B. This makes it possible to prevent positive holes from transferring to the electron transfer layer 24 and ultimately to improve light emission efficiency.

According to the above configuration, layers, other than the first electrode 21 (anode), the second electrode 26 (cathode), and the luminescent layers 23R, 23G, and 23B, can be provided as appropriate between the first electrode 21 and the second electrode 26.

<Method for Producing Organic EL Element 20>

The first electrodes 21 are formed by (i) depositing an electrode material by a method such as a sputtering method and then (ii) patterning the electrode material in shapes for respective pixels 2R, 2G, and 2B by photolithography and etching.

The first electrodes 21 can be made of any of various electrically conductive materials. Note, however, that the first electrodes 21 need to be transparent or semi-transparent in a case where the organic EL display device 1 is a bottom emission organic EL element in which light is emitted towards an insulating substrate 11 side.

In contrast, the second electrode 26 needs to be transparent or semi-transparent in a case where the organic EL display device 1 is a top emission organic EL element in which light is emitted from a side opposite to the substrate side.

Examples of the conductive film material for the first electrode 21 and the second electrode 26 encompass (i) a transparent conductive material such as ITO (indium tin oxide), IZO (indium zinc oxide), and gallium-added zinc oxide (GZO) and (ii) a metal material such as gold (Au), nickel (Ni), and platinum (Pt).

Examples of the first electrode 21 and the second electrode 26 encompass a sputtering method, a vacuum vapor deposition method, a chemical vapor deposition (CVD) method, a plasma CVD method, and a printing method. For example, the first electrode 21 can be stacked by use of the vapor deposition device 1 (later described) in accordance with Embodiment 1.

The organic EL layer can be made of a known material. For example, each of the luminescent layers 23R, 23G, and 23B is made of a single material or made of one material serving as a host material mixed with another material serving as a guest material or a dopant.

The hole injection layer and the hole transfer layer or the hole injection layer/hole transfer layer 22 can be made of, for example, a material such as anthracene, azatriphenylene, fluorenone, hydrazone, stilbene, triphenylene, benzine, styryl amine, triphenylamine, porphyrin, triazole, imidazole, oxadiazole, oxazole, polyarylalkane, phenylenediamine, arylamine, or a derivative of any of the above, a monomer, an oligomer, or a polymer of a chain-like or cyclic conjugated system, such as a thiophene compound, a polysilane compound, a vinylcarbazole compound, or an aniline compound.

The luminescent layers 23R, 23G, and 23B are each made of a material, such as a low-molecular fluorescent pigment or a metal complex, which has high light emission efficiency. For example, the luminescent layers 23R, 23G, and 23B are each made of a material such as anthracene, naphthalene, indene, phenanthrene, pyrene, naphthacene, triphenylene, perylene, picene, fluoranthene, acephenanthrylene, pentaphene, pentacene, coronene, butadiene, coumarin, acridine, stilbene, a derivative of any of the above, a tris(8-quinolinate) aluminum complex, a bis(benzoquinolinate) beryllium complex, a tri(dibenzoylmethyl)phenanthroline europium complex, ditoluyl vinyl biphenyl, hydroxyphenyl oxazole, or hydroxyphenyl thiazole.

Each of the electron transfer layer 24 and the electron injection layer 25 or the electron transfer layer/electron injection layer can be made of, for example, a material such as a tris(8-quinolinate) aluminum complex, an oxadiazole derivative, a triazole derivative, a phenylquinoxaline derivative, or a silole derivative.

<Method for Forming Film Formation Pattern by Vacuum Vapor Deposition Method>

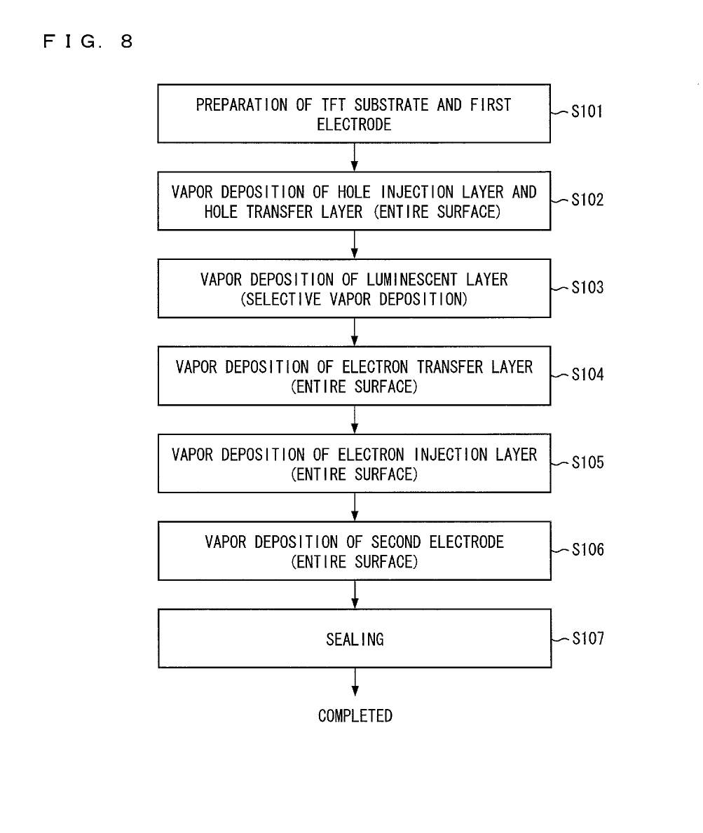

The following description will discuss a method of forming a film formation pattern with the use of a vacuum vapor deposition method, mainly with reference to FIG. 8.

Note that the description below will discuss an example in which (i) the TFT substrate 10 is employed as the film formation substrate (film formation object), (ii) an organic luminescent material is employed as a vapor deposition material, and (iii) an organic EL layer is formed as a vapor deposition film on the film-formation substrate, on which the first electrode 21 has been formed, with the use of the vacuum vapor deposition method.

According to the full-color organic EL display device 1, for example, the pixels 2R, 2G, and 2B, each of which is constituted by a corresponding one of the organic EL elements 20 having the respective luminescent layers 23R for red (R), 23G for green (G), and 23B for blue (B), are arranged in a matrix manner as above described.

Note that, instead of the luminescent layers 23R, 23G, and 23B for the respective red (R), green (G), and blue (B), it is possible to provide (i) luminescent layers for, for example, cyan (c), magenta (M), and yellow (Y) or (ii) luminescent layers for respective red (R), green (G), blue (B), and yellow (Y).

According to the organic EL display device 1 having such a configuration, a color image is displayed, with the use of the TFTs 12, by causing the organic EL elements 20 to selectively emit light having desired luminance.

Under the circumstances, in a case where the organic EL display device 1 is produced, it is necessary to form, in a predetermined pattern on the film formation substrate, luminescent layers which are made of organic luminescent materials for emitting colored lights, for the respective organic EL elements 20.

As described earlier, the vapor deposition mask 300 has the openings 301 each of which has a desired shape and which are provided at desired locations. The vapor deposition mask 300 is provided so as to be away from a film formation surface 201 of the film formation substrate 200 (see FIG. 1).

On the opposite side of the film formation substrate 200 with respect to the vapor deposition mask 300, the vapor deposition particle emitting device 501 is provided as the vapor deposition source so as to face the film formation surface 201 of the film formation substrate 200.

In a case where the organic EL display device 1 is produced, the organic luminescent material is vapor-deposited or sublimated into gas form under high vacuum so that the organic luminescent material is emitted from the emission holes 111 of the nozzle section 110 as gaseous vapor deposition particles.

The vapor deposition material, which has been emitted from the emission holes 111 serving as the vapor deposition particles, is vapor-deposited on the film formation substrate 200 via the openings 301 provided in the vapor deposition mask 300.

This allows an organic film, which has a desired film formation pattern, to be vapor-deposited as a vapor deposition film only in desired locations on the film formation substrate 200 which locations correspond to the openings 301 of the vapor deposition mask 300. Note that the vapor depositions are made for colors of the respective luminescent layers (this process is referred to as “selective vapor deposition”).

For example, in a case of the hole injection layer/hole transfer layer 22 illustrated in FIG. 7, film formation is carried out all over the display section, and therefore an open mask, which has only an opening for all over the display section and an opening for area(s) in which the film formation is required, is employed as the vapor deposition mask 300.

Note that the same applies to the electron transfer layer 24, the electron injection layer 25, and the second electrode 26.

In a case where the luminescent layer 23R (see FIG. 7) for a pixel which displays red is formed, film formation is carried out by using, as the vapor deposition mask 300, a fine mask having an opening for an area in which a red luminescent material is to be vapor-deposited.

<Flow of Producing Organic EL Display Device 1>

FIG. 8 is a flowchart illustrating, in a processing order, processes of producing the organic EL display device 1.

First, a TFT substrate 10 is prepared, and a first electrode 21 is formed on the TFT substrate 10 (S101). Note that the TFT substrate 10 can be prepared with the use of a known technique.

Then, with the use of a vacuum vapor deposition method, a hole injection layer and a hole transfer layer are formed all over pixel area on the TFT substrate 10, on which the first electrode 21 has been formed, while using an open mask as the vapor deposition mask 300 (S102). Note that a hole injection layer/hole transfer layer 22 can be formed instead of the hole injection layer and the hole transfer layer, as early described.

Next, luminescent layers 23R, 23G, and 23B are formed by making a selective vapor deposition by use of the vacuum vapor deposition method, while using a fine mask as the vapor deposition mask 300 (S103). This causes patterned films for the respective pixels 2R, 2G, and 2B to be formed.

Subsequently, an electron transfer layer 24, an electron injection layer 25, and a second electrode 26 are sequentially formed all over the pixel area on the TFT substrate 10, on which the luminescent layers 23R, 23G, and 23B have been formed, by use of the vacuum vapor deposition method, while using an open mask as the vapor deposition mask 300 (S104 through S106).

After the substrate has been subjected to a vapor deposition, as described above, an area (display section) for the organic EL element 20 is sealed so that the organic EL element are not deteriorated by moisture and oxygen in the atmosphere (S107).

Examples of the sealing encompass (i) a method in which a film, which hardly allows moisture and oxygen to pass therethrough, is formed by a CVD method or the like and (ii) a method in which a glass substrate or the like is adhered by an adhesive agent or the like.

By thus carrying out the above processes, the organic EL display device 1 is produced. The organic EL display device 1 can carry out a desired display by causing the organic EL elements 20 in the respective pixels to emit light in response to electric currents externally supplied from a driving circuit provided.

The following description will discuss functions and effects of the vapor deposition device in accordance with Embodiment 1.

<Functions and Effects>

General scanning vapor deposition will cause the following first and second problems:

The first problem is a reduction in vapor deposition rate caused by a vapor deposition jet controlling mechanism such as a restriction panel. For example, if a restriction panel allows only 1/10 of a vapor deposition jet to contribute to a vapor deposition, then the vapor deposition rate is lowered to 1/10 of a value obtained when no restriction plate is employed. For example, in a case where a vapor deposition material is emitted, at a vapor deposition rate of 1 nm/s, from emission holes of a vapor deposition source, an actual vapor deposition rate at which the vapor deposition material is vapor-deposited on a substrate is 0.1 nm/s.

The second problem is a need for a high vapor deposition rate due to the principle of scanning vapor deposition. That is, scanning vapor deposition allows a vapor deposition material to be vapor-deposited on a substrate only while the substrate is moving past openings of a small vapor deposition mask. As such, vapor deposition can only be made during a time period that is obtained through dividing a scanning-direction length of the vapor deposition mask by a scanning rate of the substrate. For example, in a case where (i) the whole length of the openings of the vapor deposition mask is 150 mm and (ii) the scanning rate of the substrate is 15 mm/s, the duration of vapor deposition on a given area of the substrate is 10 seconds. As such, in a case where the length of the substrate is 750 mm, the length of time required for the vapor deposition all over the substrate is 50 seconds.

If a vapor deposition is to be made, all over the substrate all at once, so as to have a thickness of 50 nm, then a vapor deposition rate required is 1 nm/s (50 (nm)/50 (s)=1 nm/s). In contrast, if vapor deposition is to be made so as to have a thickness of 50 nm while scanning a substrate as is the case of scanning vapor deposition, then a vapor deposition rate required is 5 nm/s (50 (nm)/10 (s)=5 nm/s).

As is clear from above, general scanning vapor deposition thus faces a trade-off between the first problem of a reduction in vapor deposition rate and the second problem of a need for a high vapor deposition rate. Of course, it is possible to obtain, despite a low vapor deposition rate, a vapor-deposited film having a sufficient thickness by repeating a scanning process multiple times so as to increase an entire amount of time for vapor deposition. This, however, causes an increase in takt time (overall period from the introduction of a substrate until the retrieval of the substrate).

There is a method that can solve the problems by increasing a temperature at which a vapor deposition in a vapor deposition source is heated up. This causes an increase in vapor deposition rate.

A crucible is, however, typically supplied with powdery vapor deposition material or a block of vapor deposition material.

While a crucible is being heated, part of a vapor deposition material, which part is in contact with an inner wall of the crucible, is first heated, and then the rest of the crucible is heated through heat conduction of the vapor deposition material.

This means that an increase in the temperature of a vapor deposition material is dependent on thermal conductivity of the vapor deposition material. Nevertheless, a typical organic material to be used for an organic EL element has lower thermal conductivity than that of metal. This causes part of a vapor deposition material, which part is in close proximity to an inner wall of a crucible, to be excessively heated before the entire vapor deposition material is sufficiently heated. It follows that thermal degradation occurs. Hence, there is a limit to the increase in a vapor deposition rate by increasing a heating temperature. In the example discussed in the earlier paragraphs, for example, if the vapor deposition rate is increased, by an increase in the heating temperature, up to 10 nm/s without causing thermal degradation, then a net (actual) vapor deposition rate on the substrate is 1 nm/s.

There is another method of increasing a vapor deposition rate in which vapor depositions are made simultaneously by two or more vapor deposition sources which are juxtaposed.

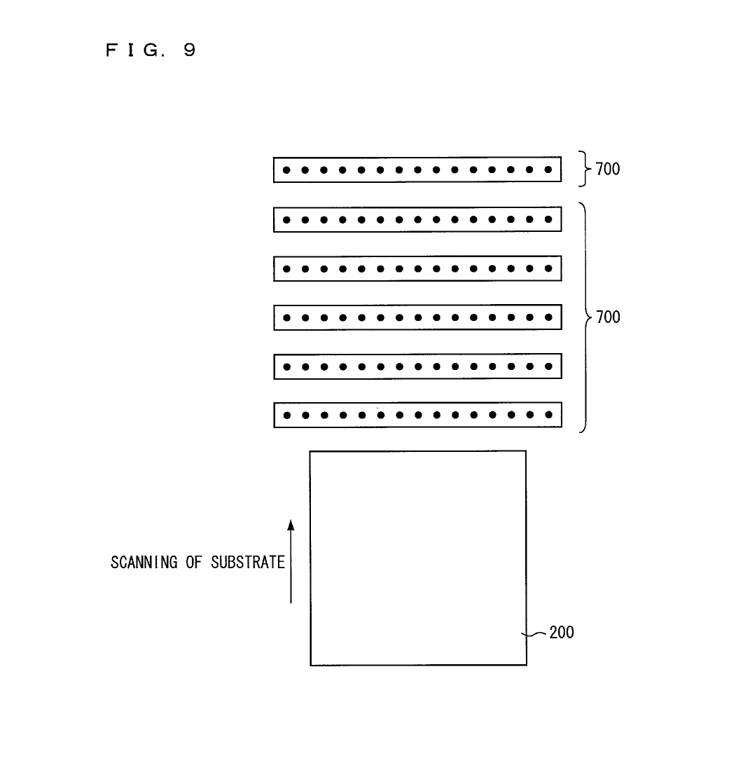

FIG. 9 is a view schematically illustrating a vapor deposition processing system for comparison with the vapor deposition processing system illustrated in FIG. 5.

According to the vapor deposition processing system illustrated in FIG. 9, (i) six lines of vapor deposition sources 700 and a film formation substrate 200 are employed and (ii) vapor depositions are simultaneously made by five of the six lines vapor deposition sources 700 while the film formation substrate 200 is being moved in a scanning direction.

This makes it possible to produce a vapor deposition rate of 5 nm/s in effect (1 nm/s×5=5 nm/s), which is a vapor deposition rate necessary in light of the second problem described earlier. Note that the remaining one vapor deposition source 700, which has not been used, is for replacement of a vapor deposition material, and is in a stand-by state. In a case where one of the five vapor deposition sources 700 runs out of a vapor deposition material, (i) the remaining one vapor deposition source 700 is operated instead so as to resupply a new vapor deposition material, (ii) the vapor deposition source 700, which has run out of the vapor deposition material, is replaced with a new vapor deposition source 700, and then (iii) the new vapor deposition source 700 is put in a stand-by state.

Note that the vapor deposition processing system illustrated in FIG. 9 will cause the following problem.

First, since the vapor deposition sources 700 are integrated with the vapor deposition mask, it is necessary to prepare as many vapor deposition masks as the number of added vapor deposition sources 700. This gives rise to an increase in equipment cost because a vapor deposition mask requires high-precision processing of fine openings.

Second, it is necessary to align the film formation substrate 200 with individual vapor deposition masks. Such an alignment should be carried out by moving a vapor deposition unit. This is because, if the film formation substrate 200 is moved so as to be aligned with a vapor deposition mask, then there occurs displacement of the film formation substrate 200 from the other vapor deposition masks. Note that, the vapor deposition unit includes (i) a mechanism for fixing vapor deposition sources and respective vapor deposition masks together and (ii) a heater. Hence, the vapor deposition unit is significantly heavier than the film formation substrate 200. This causes such a mechanism for alignment to be complex and large in scale, and ultimately causes an increase in cost of equipment as well. This further causes a reduction in alignment accuracy because of great momentum caused by the heavy weight of the vapor deposition unit.

Third, since the plurality of vapor deposition sources 700 simultaneously emit vapor deposition jets, a vapor deposition material emitted as vapor deposition jets is wasted while the film formation substrate 200 is not located above vapor deposition masks of the respective vapor deposition sources 700 from which the vapor deposition jets are emitted. For example, in a case where (i) vapor deposition is made by each vapor deposition source 700 for 15 seconds and (ii) five of the vapor deposition sources 700 emit vapor deposition jets simultaneously, a vapor deposition material is wasted for the total of 60 seconds (15 seconds×4 lines=60 seconds), which is the sum of respective amounts of time for which vapor deposition is made by four vapor deposition sources 700 above which the film formation substrate 200 is not located.

It is thus difficult to increase a vapor deposition rate in general scanning vapor deposition. In addition, even if a vapor deposition rate can be increased, the above-described three problems then arise, as is the case of the vapor deposition processing system illustrated in FIG. 9.

Note that although the vapor deposition rate could be increased by a method of reducing the restriction of vapor deposition jets placed by a restriction panel, such a method is unrealistic. This is because a reduction in restriction of vapor deposition jets placed by a restriction panel will cause the following problems: (i) a vapor deposition blur will be enlarged (i.e. a blurring pattern will be enlarged, the pattern being made up of each part having a width that is wider than a width of each opening of a vapor deposition mask), (ii) emission holes, the restriction panel, a film formation substrate, openings of a vapor deposition mask, and the like will be subject to displacement, and (iii) variations in thickness, position, width, and the like of a vapor deposition film, which variations are caused by formation accuracy of a pattern, will be large. This makes it difficult to form a vapor deposition film in a highly precise pattern. Such a difficulty brings about the following problems: (I) an inability to produce a large organic EL display device and a high-resolution organic EL display device and (II) a reduction in yield.

In contrast, with the vapor deposition device in accordance with Embodiment 1, it is possible to solve various problems caused by the above-described scanning vapor deposition.

Specifically, the vapor deposition processing system, in which the vapor deposition device according to Embodiment 1 is employed, (i) includes the six lines of vapor deposition particle emitting devices 501 juxtaposed in a direction in which relative scanning of the film formation substrate 200 is to be carried out and (ii) is configured so that only one of the six lines of vapor deposition particle emitting devices 501 is integrated with the vapor deposition mask 300 so as to make up a vapor deposition source unit 600 (see FIG. 5). That is, while the vapor deposition processing system illustrated in FIG. 9 is configured so that five of the six lines of vapor deposition sources 700 simultaneously emit vapor deposition particles, the vapor deposition processing system illustrated in FIG. 5 is configured so that (a) only one of the six lines of vapor deposition particle emitting devices 501 emits vapor deposition particles and (b) the remaining five vapor deposition particle emitting devices 501 do not emit vapor deposition particles.

The vapor deposition source unit 600 is configured to emit, by heating up the heating plates 101 making up the heating plate unit 100 provided inside the nozzle section 110, vapor deposition particles adhering to the surfaces 101a of the respective heating plates 101. In so doing, vapor deposition can be made without the need to heat up the heating plates 101 each to a temperature lower than that at which the crucible 123 provided inside the vapor deposition particle generating section 120 is heated. This is because the vapor deposition particles are not in the form of a block, and heat can therefore be easily conducted through the vapor deposition particles adhering to the surfaces 101a of the respective heating plates 101.

It is therefore possible to increase, without increasing the temperature of the vapor deposition particles by much, a vapor deposition rate at which the vapor deposition particles that are emitted from the heating plates 101 are emitted from the emission holes 111 of the nozzle section 110, provided that the vapor deposition particles do need to be heated up to a temperature equal to or more than a vaporizing/sublimating temperature of a vapor deposition material 124.

Note that in a case where a vapor deposition rate required for vapor deposition needs to be 5 nm/s as described earlier, a vapor deposition rate, at which vapor deposition particles are emitted from the vapor deposition source unit 600, need only be set to 50 nm/s which is, in view of an influence of the restriction plate 131, 10 times as high as the vapor deposition rate required for the vapor deposition.

That is, a vapor deposition rate of 50 nm/s, at which vapor deposition particles are emitted from the emission holes 111 of the nozzle section 110, is obtained by heating the nozzle section 110 in the vapor deposition particle emitting device 501 of the vapor deposition source unit 600. This makes it possible to obtain a vapor deposition rate of 5 nm/s that is a net (actual) vapor deposition rate at which the vapor deposition particles, that have passed through the restriction plate 131, are vapor-deposited on the film formation substrate 200.

Meanwhile, vapor deposition particles, which have been produced by transforming a vapor deposition material 124 into gaseous form, are supplied, at a rate of 10 nm/s, from a vapor deposition particle generating section 120 (see FIG. 1) to a nozzle section 110 (see FIG. 1) of each of the five remaining vapor deposition particle emitting devices 501 from which no vapor deposition particle is emitted. The vapor deposition particles are simultaneously supplied to the nozzle sections 110 of the five individual vapor deposition particle emitting devices 501. In so doing, (i) the heating plate units 100 in the respective nozzle sections 110 and (ii) inner wall surfaces of the nozzle sections 110 which inner wall surfaces are located in the vicinity of the respective heating plate units 100, are cooled down. This causes the vapor deposition particles to adhere to surfaces of the heating plate units 100 and to the inner wall surfaces.

In other words, while the vapor deposition source unit 600 is emitting vapor deposition particles, the remaining five vapor deposition particle emitting devices 501 each generate, therein, vapor-deposition-particle adhered objects to which vapor deposition particles have adhered (such an object is generated by a vapor deposition material remaining on the surfaces of the heating plate 101).

Subsequently, when each of the five vapor deposition particle emitting devices 501 makes up a vapor deposition source unit 600, a vapor deposition rate of 50 nm/s, at which vapor deposition particles are emitted from the emission holes 111, is obtained by heating the nozzle section 110. This allows a vapor deposition rate of 5 nm/s, which is a net (actual) vapor deposition rate with the influence of the restriction plate 131, to be obtained. This, as described earlier, is a desirable vapor deposition rate.

According to the vapor deposition processing system of Embodiment 1, the vapor deposition rate is five times as high as that of a general vapor deposition processing system. This causes a length of time for total consumption of a vapor deposition material 124 to be ⅕, accordingly. However, since the six lines of the vapor deposition particle emitting devices 501 are used in order one at a time, it is possible to supply a vapor deposition material 124 to the nozzle section 110 of each of five suspended vapor deposition particle emitting devices 501 while one vapor deposition particle emitting device 501 is being used. This makes it possible to solve the problems (material deterioration due to increases in vapor deposition rate and in heating temperature) that occur in the vapor deposition processing system illustrated in FIG. 9.

Furthermore, according to the vapor deposition processing system of Embodiment 1, only one vapor deposition mask 300 is needed since only one vapor deposition particle emitting device 501 at a time is to emit vapor deposition particles. Hence, not only is it unnecessary to prepare as many vapor deposition masks 300 as the number of vapor deposition particle emitting devices 501, but it is also possible to align the film formation substrate 200 with the vapor deposition mask 300 by moving the film formation substrate 200 instead of moving the vapor deposition source unit 600. This (i) makes it possible to prevent an alignment mechanism from being complex and high-priced and (ii) makes it easy to increase the number of vapor deposition particle emitting devices 501 to be juxtaposed.

Since the number of vapor deposition particle emitting devices 501, which are vapor deposition sources, is increased, it is possible to further reduce the vapor deposition rate at which vapor deposition particles are supplied from a vapor deposition particle generating section 120 to a nozzle section 110. This allows a further reduction in material deterioration.

Although the number of vapor deposition particle emitting devices 501 is increased, only one vapor deposition source operates (emits vapor deposition particles) at a time. As such, no waste of a vapor deposition material occurs, unlike the case where a plurality of vapor deposition sources are simultaneously used.

The vapor deposition device of Embodiment 1 is summarized as follows. A vapor deposition material is in advance made to adhere to surfaces 101a of heating parts (structures such as fins each having large surface area) such as heating plates 101 which make up a heating plate unit 100 inside a nozzle section 110 of a vapor deposition particle emitting device 501 (vapor deposition source). This causes vapor-deposition-particle adhered objects, each having surfaces on which the vapor deposition material is remaining, to be formed. The vapor-deposition-particle adhered objects serve as sub-vapor deposition particle generating sections apart from a vapor deposition particle generating section 120.

Then, a vapor deposition rate is increased by all of the sub-vapor deposition particle generating sections at once. This brings about the following advantageous effects:

1) The vapor deposition material remaining on the surfaces of the sub-vapor deposition particle generating sections can be heated rapidly and evenly, regardless of thermal conductivity of the vapor deposition material. This allows (i) an increase in the vapor deposition rate even at a low temperature and (ii) a reduction in thermal degradation of the vapor deposition material.

2) Since a rapid temperature increase for the generation of vapor deposition particles is possible, it is possible to shorten a length of time required for stabilizing the vapor deposition rate. This allows a reduction in loss of a vapor deposition material.

3) For an increase in vapor deposition rate, vapor deposition sources and a vapor deposition mask simultaneously operate without the need for alignment. This allows for high-precision pattern formation.

Note that, according to Embodiment 1, the cooling device 150 and the heating device 160, provided in the vapor deposition particle emitting devices 501, are used to carry out the steps, i.e., from (i) the step of causing vapor deposition particles to adhere to the heating plates 101 to (ii) the (heating) step of transforming the vapor deposition material, which is remaining on the heating plates 101, back into gaseous form. Embodiment 1 is, however, not limited to such. Alternatively, it is possible that (a) the vapor deposition particle emitting device 501 can be configured to carry out only the step of transforming a vapor deposition material, which is remaining on the heating plates 101, back into gaseous form and (b) the step of causing vapor deposition particles to adhere to the heating plates 101 is carried out by a separate device. Embodiment 2 below will discuss an example in which (I) a separate device carries out the step of causing vapor deposition particles to adhere to heating plates and then causing the vapor deposition material to remain on respective surfaces of the heating plates and (II) a vapor deposition particle emitting device carries out only the step of transforming the vapor deposition material back in to gaseous form.

### Embodiment 2

The following description will discuss Embodiment 2 of the present invention. For convenience, members similar in function to the members described in Embodiment 1 are given the same reference numerals accordingly, and the detailed descriptions of such members are omitted.

<Description of Entire Vapor Deposition Device>

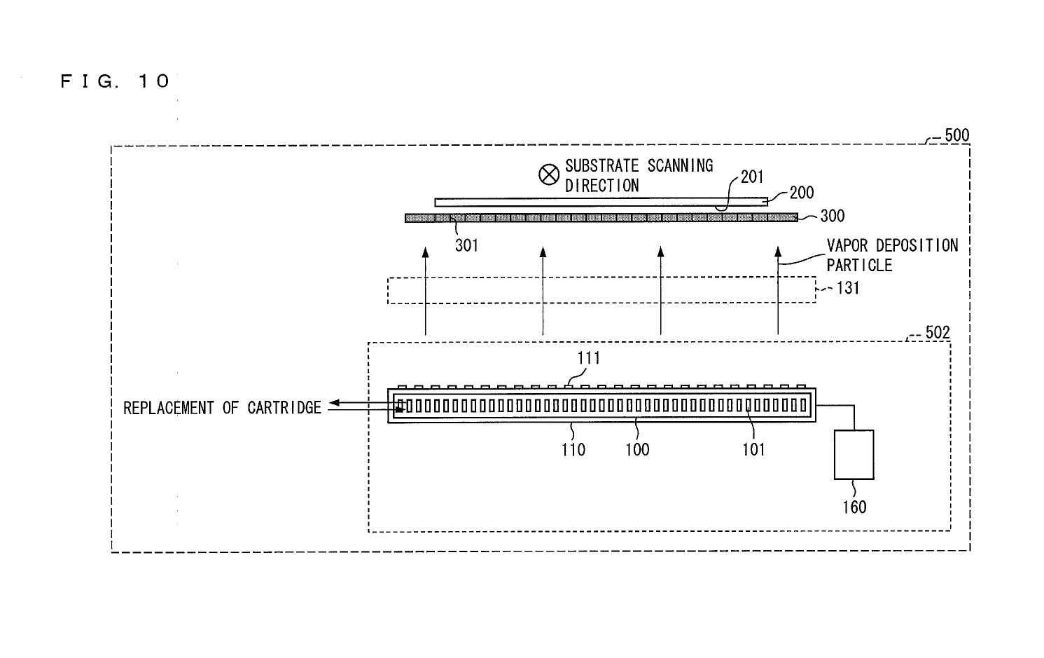

FIG. 10 is a view schematically illustrating an entire vapor deposition device that includes a vapor deposition particle emitting device in accordance with Embodiment 2 of the present invention.

As illustrated in FIG. 10, the vapor deposition device includes a vapor deposition particle emitting device 502, serving as a vapor deposition source, in a vacuum chamber 500. The vapor deposition particle emitting device 502 includes a nozzle section (vapor deposition particle emitting section) 110 having a plurality of emission holes 111.

The vapor deposition particle emitting device 502 is fundamentally identical in configuration to the vapor deposition particle emitting devices 501, except that the vapor deposition particle emitting device 502 is configured so that vapor deposition particles do not adhere, while in the nozzle section 110, to heating plates 101 of a heating plate unit 100.

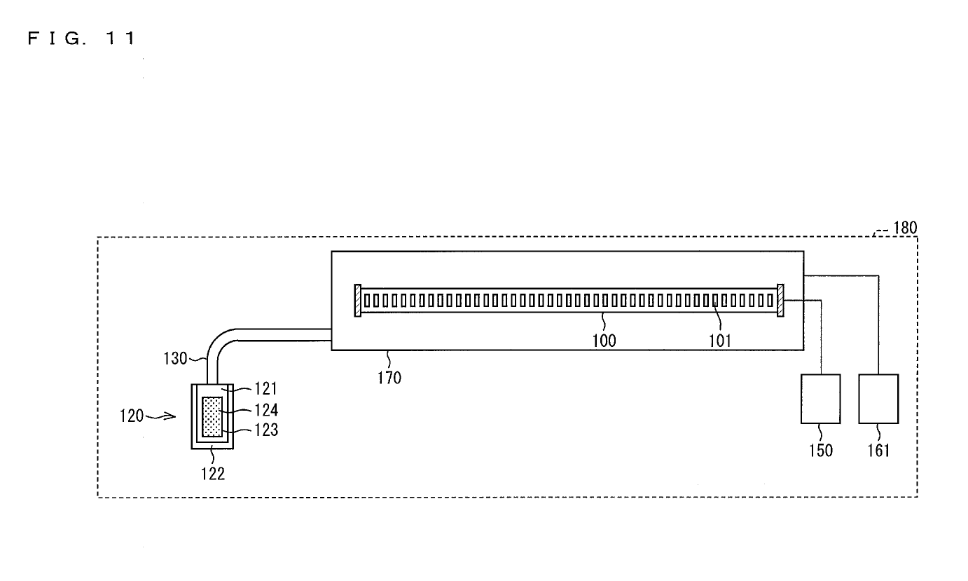

According to Embodiment 2, vapor deposition particles adhere to the heating plates 101 while the heating plate unit 100 is located in a vapor deposition material filling device 180 (see FIG. 11) which is provided outside the vacuum chamber 500. This means that, according to Embodiment 2, a vapor deposition particle emitting system is made up of (i) the vapor deposition particle emitting device 502 serving as a vapor deposition source and (ii) the vapor deposition material filling device 180. The vapor deposition material filling device 180 will be described later in detail.

According to the vapor deposition particle emitting device 502, the heating plate unit 100, which is in the form of a cartridge, is attachable to or detachable from the nozzle section 110. Other than that, the vapor deposition particle emitting device 502 is configured so that, as is the case of the vapor deposition particle emitting devices 501, (i) a heating device 160 heats up the heating plates 101 (sub-vapor deposition particle generating sections) to which vapor deposition particles are adhering, so that a vapor deposition material, which is remaining on the heating plates 101, is transformed back into gaseous form and then (ii) gaseous vapor deposition particles are emitted out from the emission holes 111.

Therefore, advantageous effects similar to those brought about in Embodiment 1 can be brought about. Specifically, the following advantageous effects can be brought about: 1) The vapor deposition material remaining on the surfaces of the sub-vapor deposition particle generating sections can be heated rapidly and uniformly, regardless of thermal conductivity of the vapor deposition material. This allows (i) the vapor deposition rate to be increased even at a low temperature and (ii) a reduction in thermal degradation of the vapor deposition material. 2) Since a rapid temperature increase for the generation of vapor deposition particles is possible, it is possible to shorten a length of time required for stabilizing the vapor deposition rate. This allows for a reduction in loss of a vapor deposition material. 3) For an increase in vapor deposition rate, vapor deposition sources and a vapor deposition mask simultaneously operate without the need for alignment. This allows for high-precision pattern formation.

Furthermore, according to Embodiment 2, no member equivalent to the vapor deposition particle generating section 120 is provided in the vapor deposition particle emitting device 502. This brings about an effect of downsizing the vacuum chamber 500.

<Vapor Deposition Material Filling Device 180>

As illustrated in FIG. 11, the vapor deposition material filling device 180 is substantially identical in configuration to the vapor deposition particle emitting devices 501 illustrated in FIG. 1, except that the vapor deposition material filling device 180 includes a heating container (filling container) 170 for containing the heating plate unit 100, instead of a nozzle section 110 for containing a heating plate unit 100. Note, however, that the vapor deposition material filling device 180 is identical to the vapor deposition particle emitting devices 501 in that vapor deposition particles are made to adhere to surfaces of the heating plates 101 of the heating plate unit 100.

Embodiment 2 is also similar to Embodiment 1 in process of causing vapor deposition particles to adhere to the surfaces of the heating plates 101, provided that (i) the heating container 170 is heated by a heating device 161 to such an extent so as not to exceed a temperature at which a vapor deposition material adheres to the heating container 170 and (ii) the heating plate unit 100 is cooled by a cooling device 150 to such an extent that a vapor deposition material adheres to the heating plate unit 100. That is, a temperature in the heating container 170 is controlled so as to cause, as far as possible, gaseous vapor deposition particles, which have been supplied from a vapor deposition particle generating section 120 to an introduction tube 130, to adhere only to the heating plate unit 100.

The heating plate unit 100 is also configured so that vapor deposition particles adhere not only to the heating plates 101 but also to a cartridge-shaped housing (not illustrated) containing the heating plate unit 100. This makes it possible to transform, all at once into gaseous form, (i) vapor deposition particles adhering to the heating plates 101 and (ii) vapor deposition particles adhering to the cartridge-shaped housing. It is therefore possible to further increase a vapor deposition rate.

When an entire portion of vapor deposition particles adhere to the heating plate unit 100, the heating plate unit 100 is (i) taken out of the vapor deposition material filling device 180 and then (ii) inserted into the nozzle section 110 of the vapor deposition particle emitting device 502 provided in the vacuum chamber 500. Subsequently, the heating device 160 heats up the nozzle section 110, so that (a) the vapor deposition material (vapor deposition particles) remaining on the heating plates 101 is transformed into gaseous form and then (b) the gaseous vapor deposition particles are emitted out of the emission holes 111.

Note that, according to the vapor deposition device of Embodiment 1 in which the heating plate unit 100 is fixed inside the nozzle section 110, when vapor deposition particles adhering to the heating plates 101 are no longer present, it is necessary to cool down the nozzle section 110 so that new vapor deposition particles adhere to the heating plates 101. This disables the vapor deposition device from making vapor deposition during a cooling period in which the nozzle section 110 is cooled down (i.e. during vapor deposition particle adhering period). Therefore, the vapor deposition device of Embodiment 1 is configured so that the plurality of vapor deposition particle emitting devices 501, which serve as vapor deposition sources, are juxtaposed. This causes, during a period in which a nozzle section 110 of any given vapor deposition particle emitting device 501 is cooled down, vapor deposition to be made by one of the remaining vapor deposition particle emitting devices 501 which one has heating plates 101 to which vapor deposition particles are adhering.

On the other hand, the vapor deposition device of Embodiment 2 is configured so that vapor deposition particles adhere to the heating plates 101 of the heating plate unit 100 while the heating plate unit 100 is in the vapor deposition material filling device 180 which is provided separately from the vapor deposition particle emitting device 502. This eliminates the cooling period (the vapor deposition particle adhering period).

Specifically, the vapor deposition device of Embodiment 2 is configured so that, when a certain amount of vapor deposition particles, which have adhered to heating plates 101 of a heating plate unit 100, have been transformed into gaseous form, (i) the heating plate unit 100 is taken out of the nozzle section 110 and then (ii) another heating plate unit 100, which has heating plates 101 to which vapor deposition particles have been adhered, is loaded into the nozzle section 110.

Hence, it is unnecessary to provide a plurality of vapor deposition particle emitting devices 502 each serving as a vapor deposition source. Rather, there needs to be only one vapor deposition source provided.

Furthermore, according to the vapor deposition device of Embodiment 2, the vapor deposition material filling device 180 is separately provided. As such, a vapor deposition rate of the vapor deposition particle emitting device 502 is independent of a vapor deposition rate at which vapor deposition particles are supplied from a crucible 123 of the vapor deposition particle generating section 120.

For instance, according to Embodiment 1, a vapor deposition particle emitting device 501 has a function identical to that of the vapor deposition material filling device 180. Therefore, the lower a vapor deposition rate at which vapor deposition particles are supplied from the crucible 123 of the vapor deposition particle generating section 120, the greater the number of vapor deposition particle emitting devices 501 needed, which serve as vapor deposition sources and are juxtaposed. This causes the vacuum chamber 500 to be large in size, accordingly.

According to Embodiment 2, on the other hand, there is always provided only one vapor deposition particle emitting device 502, serving as a vapor deposition source, in the vacuum chamber 500. Therefore, it is only the number of vapor deposition material filling devices 180 that is to be increased, as needed, which vapor deposition material filling devices 180 are provided outside the vacuum chamber 500. This prevents the vacuum chamber 500 from excessively upsizing.

Note that the vacuum chamber 500 becomes large in volume because the vacuum chamber 500 includes other mechanisms such as a mechanism for alignment of the vapor deposition mask 300 with the film formation substrate 200. In regard to the vapor deposition material filling device 180, however, the heating container 170 can be made small in volume because there are no members, other than a heating plate unit 100, to be loaded into the heating container 170. This allows (i) the vapor deposition material filling device 180 to be downsized and simplified and (ii) a reduction in length of time for depressurization of the vacuum chamber 500. This ultimately leads to a reduction in equipment cost of the vapor deposition device. At the same time, the number of vapor deposition material filling devices 180 can be easily increased. This allows a further reduction in vapor deposition rate of the vapor deposition particle generating section 120, and therefore allows a further reduction in thermal degradation of a vapor deposition material.

Furthermore, according to Embodiment 2, there is no need to cause vapor deposition particles to adhere to a heating plate unit 100 while in the nozzle section 110. Accordingly, it is unnecessary to secure a space in which to cause gaseous vapor deposition particles to remain so as to be cooled down. This allows the nozzle section 110 to be downsized, and therefore allows a reduction in equipment cost of the vapor deposition device.

A heating plate unit 100, which is in the form of a cartridge, is replaced with a new one when vapor deposition particles, which have adhered to surfaces of heating plates 101, are all exhausted. Then, vapor deposition can be continuously made by sequentially replacing a heating plate unit 100 with a new one.

Note that it is possible that, before being inserted into the nozzle section 110, the heating plate unit 100 is, in the vacuum chamber 500 or in a supplemental chamber provided in addition to the vacuum chamber 500, heated up to an approximate temperature less than a vaporizing/sublimating temperature of vapor deposition particles so that, when inserted into the nozzle section 110, the heating plate unit 100 can be rapidly heated so as to be in a state in which the desired vapor deposition rate is obtained.

It is also possible to juxtapose a plurality of nozzle sections 110. For example, in a case where two nozzle sections 110 are juxtaposed and are alternately used, vapor deposition can be continued even (i) during replacement of a heating plate unit 100 with a new one and (ii) during a time period until a vapor deposition rate is stabilized. This allows for uninterrupted vapor deposition.

### Embodiment 3

The following description will discuss Embodiment 3 of the present invention.

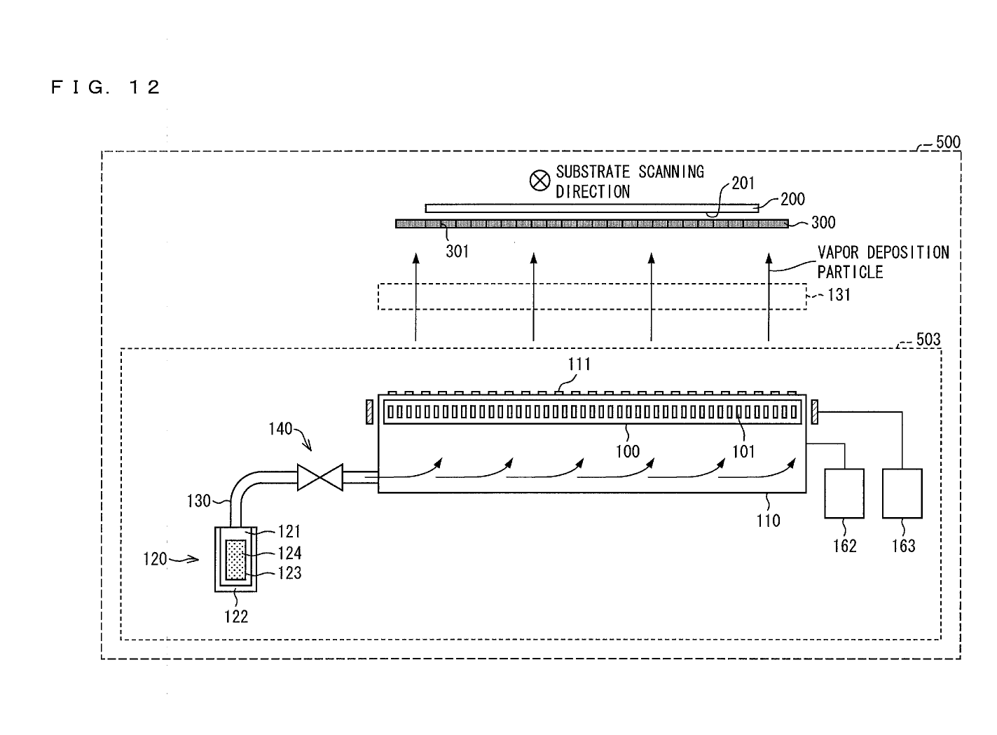

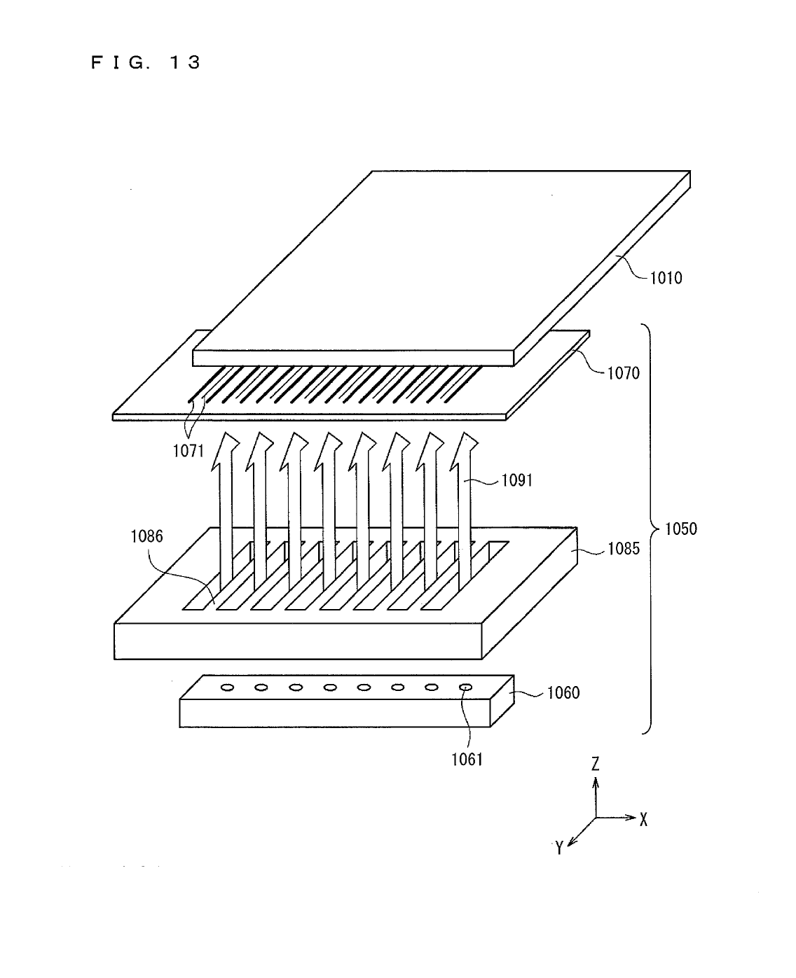

Embodiment 3 is fundamentally identical in configuration to Embodiment 1, except that a vapor deposition particle emitting device 503 (see FIG. 12) is provided instead of the vapor deposition particle emitting device 501 illustrated in FIG. 1.

The vapor deposition particle emitting device 503 includes a first heating device 162 and a second heating device 163 (see FIG. 12).

The first heating device 162 is configured to (i) externally heat up a nozzle section 110 serving as an emitting container for emitting vapor deposition particles and (ii) control a temperature of the nozzle section 110 so that a surface temperature of heating plates 101 of a heating plate unit 100 is not heated up to a vaporizing/sublimating temperature of a vapor deposition material.

The second heating device 163 is a device configured to (i) directly heat up the heating plate unit 100 in the nozzle section 110 and (ii) control the temperature of the nozzle section 110 so that the surface temperatures of the heating plates 101 are not less than the vaporizing/sublimating temperature of the vapor deposition material.

According to the vapor deposition particle emitting device 503, in a case where vapor deposition particles are to adhere to the heating plates 101, only the first heating device 162 is operated so as to heat up the nozzle section 110. In this case, the surface temperature of the heating plates 101 is controlled so as not to heated up to the vaporizing/sublimating temperature of the vapor deposition material. This causes gaseous vapor deposition particles, which have been supplied into the nozzle section 110, to adhere to the heating plates 101.

In a case where the vapor deposition particles, which have adhered to the heating plates 101, are to be transformed back into gaseous form, both the first heating device 162 and the second heating device 163 are operated so as to heat up the nozzle section 110. This causes the surfaces of the heating plates 101 to be heated up so as to be not less than the vaporizing/sublimating temperature of the vapor deposition material. As such, highly dense gaseous vapor deposition particles are emitted out of emission holes 111 of the nozzle section 110, while the vapor deposition material on the surfaces of the heating plates 101 is being transformed into gaseous vapor deposition particles.

By thus employing the two heating devices (first heating device 162 and second heating device 163), it is possible to take prompt action in a case where a vapor deposition material remaining on the heating plates 101 is to be transformed back into gaseous form. This is because (i) the nozzle section 110 is externally heated by the first heating device 162 when vapor deposition particles are to adhere to the heating plates 101 and (ii) heat thus generated by the first heating device 162 contributes to preheating of the heating plate unit 100.

Note that, according to Embodiment 1, the nozzle section 110 is to be actively cooled down in a case where vapor deposition particles are to adhere to the heating plates 101 of the heating plate unit 100. This allows the vapor deposition particles to rapidly adhere to the heating plates 101 of the heating plate unit 100 which has already been heated. In contrast, according to Embodiment 3, the nozzle section 110 is only heated instead of being cooled at all as described above.

That is, according to Embodiment 3, unlike Embodiment 1, the nozzle section 110 will never be cooled down in a case where vapor deposition particles are to adhere to the heating plates 101. Therefore, it takes an extended period of time for the heating plate unit 100 to be cooled down once the heating plate unit 100 is heated up to a temperature not less than the vaporizing/sublimating temperature of a vapor deposition material. This requires a longer period of time for adherence of the vapor deposition particles than does in Embodiment 1, and therefore causes a length of time required for a total vapor deposition process to be longer than does in Embodiment 1.

It is possible, however, to shorten a length of time required for the total vapor deposition process by, in a manner similar to FIG. 5 of Embodiment 1, (i) juxtaposing plurality of vapor deposition particle emitting devices 503 and (ii) making vapor deposition (a) during a cooling period of a nozzle section 110 of any given vapor deposition particle emitting device 503 and (b) with the use of, of all the remaining vapor deposition particle emitting devices 503, a vapor deposition particle emitting device 503 in which vapor deposition particles have adhered to surfaces of heating plates 101 of a heating plate unit 100.

<Down Deposition>

Embodiments 1 through 3 has discussed the respective examples in which vapor deposition (up deposition) is made by (i) providing vapor deposition particle emitting devices 501 through 503, respectively, below the respective film formation substrates 200 and (ii) causing the vapor deposition particle emitting devices 501 through 503, respectively, to emit vapor deposition particles upwards via the openings 301 of the respective vapor deposition masks 300. The present invention is, however, not limited to this configuration.

Alternatively, it is possible to make a vapor deposition (down deposition) by, for example, (i) providing any of vapor deposition particle emitting devices 501 through 503 above a film formation substrate 200 and (ii) causing the any of vapor deposition particle emitting devices 501 through 503 to emit vapor deposition particles downwards via openings 301 of respective vapor deposition masks 300.

In a case where a vapor deposition is thus made by such a down deposition, it is possible to precisely form a high-resolution pattern all over the film formation substrate 200, even without employing a method such as one in which an electrostatic chuck is used as a substrate holding member that holds the film formation substrate 200 for the purpose of a reduction in self-weight-induced flexure.

<Side Deposition>

Alternatively, it is also possible to make vapor deposition (side deposition) by, for example, (i) providing any of vapor deposition particle emitting devices 501 through 503 that has a mechanism that emits vapor deposition particles in lateral directions, (ii) providing a film formation substrate 200 whose film formation surface 201 faces toward the any of vapor deposition particle emitting devices 501 through 503 thus provided, and (iii) causing the any of vapor deposition particle emitting devices 501 through 503 to emit vapor deposition in lateral directions toward the film formation substrate 200 via a vapor deposition mask 300.

<Other Modifications>

An opening shape (planar shape) of each of emission holes 111 of a nozzle section 110 is not particularly limited. In fact, the emission holes 111 can each have various shapes such as a circular shape or a quadrilateral shape.

In addition, the emission holes 111 can be arranged one-dimensionally (i.e. in line) or two-dimensionally (i.e. in a surface-like manner).

In a case of a vapor deposition device in which a film formation substrate 200 and a vapor deposition mask 300 are moved relative to each other in one direction, a greater number of emission holes allows the vapor deposition device to be compatible with a film formation substrate 200 having larger surface area.

Embodiment 1 has discussed the example in which (i) the organic EL display device 1 includes the TFT substrate 10 and (ii) an organic layer is formed on the TFT substrate 10. However, the present invention is not limited to this configuration. In fact, the organic EL display device 1 can include, instead of the TFT substrate 10, a passive-type substrate on which an organic layer is to be formed without a TFT being formed. It is also possible to use the passive-type substrate as a film formation substrate 200.

While Embodiment 1 has discussed, as seen above, the example in which an organic layer is formed on the TFT substrate 10, the present invention is not limited to this configuration. In fact, the present invention is applicable to a case where the second electrode 26 is to be vapor-deposited instead of forming the organic layer. In a case where a sealing film is to be used for sealing the organic EL element 20, the present invention is applicable to vapor deposition of the sealing film.

The vapor deposition particle emitting devices 501 through 503 are suitable for, besides the method for producing the organic EL display device 1, any production method and any production device in which a film is formed in a pattern by vapor deposition. The vapor deposition particle emitting devices 501 through 503 are particularly suitable for a vapor deposition method requiring a vapor deposition source having a high vapor deposition rate.

The vapor deposition particle emitting devices 501 through 503 are suitable for, besides the organic EL display device 1, production of a functional device such as an organic thin film transistor, for example.

Embodiments 1 through 3 discussed the vapor deposition particle emitting devices 501 through 503, respectively, as vapor deposition sources of a line type. However, the vapor deposition particle emitting devices 501 through 503 are not limited to such, but can be those of a crucible type (of a point type) or those of a planar type.

The advantageous effects of the present invention are not dependent on a shape of emission holes of a nozzle section. That is, it is possible to provide multiple emission holes or to provide a single emission hole having a long opening.

The present invention is particularly effective in a case where the use is made of a material for which it usually takes an extended period of time for a vapor deposition rate to be stabilized. This is because, for example, it is possible to improve takt time (throughput) by rapidly reaching a desired vapor deposition rate (before heat sets in) even in a case where the use is made of a material, such as an organic material, which can easily deteriorate as a result of a rapid increase in temperature. Furthermore, the present invention is particularly effective in a case where the use is made of a high-cost material, such as a material for an organic layer of an organic EL element. With the present invention, a vapor deposition material can be used, even while a temperature of the vapor deposition material is being increased/decreased, for vapor deposition by (i) reducing a length of time for stabilizing a vapor deposition rate and (ii) using a plurality of vapor deposition material sources in combination. This makes it possible to make effective use of the vapor deposition material.

The vapor deposition particle emitting device of the present invention is applicable not only to production of an organic EL display device but also to production of other products in which a film is formed by vapor deposition.

Embodiment 1 has discussed the example of selective formation of a vapor deposition film in a pattern with the use of a restriction plate. However, the present invention is not limited to such, but is also applicable to a case where an organic film is formed, all at once, over an entire pixel region with the use of a vapor deposition mask having an opening that corresponds to the entire pixel region.

In a case where, for example, a hole transfer layer or the like is to be formed over the entire pixel region all at once, application of the present invention allows for an increase in vapor deposition rate. This causes a period of time for vapor deposition to be shortened, and therefore makes it possible to improve takt time of a device.

The present invention is likewise applicable to an organic EL luminescent device that is, for the purpose of illumination or the like, configured so that all of layers are formed over the entire luminescent region without being formed in a highly precise pattern. With regard to an organic EL illuminating device, in particular, a cost reduction by a reduction in takt time is remarkably effective. With the present invention, the reduction in takt time is possible since a high vapor deposition rate can be obtained.

The present invention can be applicable not only to vapor deposition of an organic film but also to vapor deposition of a second electrode and/or a sealing film.

Furthermore, the present invention is applicable not only to production of an organic EL display device but also to a production process or a product in which a film is formed by vapor deposition and therefore a vapor deposition rate is required.

It is preferable to provide the adhered object so as to be attachable to or detachable from the emitting container.

Since the adhered object is thus provided so as to be attachable to or detachable from the emitting container, it is possible to cause, with the use of a device other than a vapor deposition particle emitting device, the vapor deposition particles to adhere to the adhered object so that a vapor deposition material remains on the adhered object.

This eliminates the need to provide, in the vapor deposition particle emitting device, a device for causing the vapor deposition material to remain on the surfaces of the adhered object. Therefore, the vapor deposition particle emitting device can be made compact.

A vapor deposition particle emitting device of the present invention includes: a vapor deposition particle generating source for generating gaseous vapor deposition particles by heating a vapor deposition material; an emitting container, connected to the vapor deposition particle generating source, which has emission holes for emitting out gaseous vapor deposition particles; an adhered object, provided in the emitting container, to which vapor deposition particles adhere so that the vapor deposition material remains on a surface of the adhered object; and a surface temperature controlling device for controlling a surface temperature of the adhered object so as to be less or not less than a temperature at which the vapor deposition material becomes transformed into gaseous form.

The surface temperature controlling device can include: a cooling device for cooling the adhered object so that the surface temperature of the adhered object is less than the temperature at which the vapor deposition material becomes transformed into gaseous form; and a heating device for heating the adhered object so that the surface temperature of the adhered object is not less than the temperature at which the vapor deposition material becomes transformed into gaseous form.

With the configuration, the adhered object, which has been heated by the heating device so that the surface temperature of the adhered object is not less than a temperature at which a vapor deposition material is transformed into gaseous form, can be cooled down by the cooling device so that the surface temperature of the adhered object is at a temperature at which the gaseous vapor deposition particles can adhere to the adhered object, i.e. the surface temperature of the adhered object is lower than the temperature at which the vapor deposition material is transformed into gaseous form.

This makes it possible to shorten a period of time between (i) when the adhered object emits vapor deposition particles so as to run out of them and (ii) when new vapor deposition particles adhere to the surface of the adhered object so that a new vapor deposition material remains on the surface of the adhered object.

Therefore, it is possible to majorly reduce a total length of time required for a vapor deposition process.

The surface temperature controlling device includes: a first heating device for heating the adhered object to such an extent that the surface temperature of the adhered object is the temperature at which the vapor deposition material becomes transformed into gaseous form; and a second heating device for heating the adhered object so that the surface temperature of the adhered object is not less than the temperature at which the vapor deposition material becomes transformed into gaseous form.

According to the configuration, the first heating device heats up the surface of the adhered object, which is provided in the emitting container filled with gaseous vapor deposition particles, such that the surface of the adhered object is less than a temperature at which a vapor deposition material becomes transformed into gaseous form. This makes it possible to cause the vapor deposition particles to adhere to the surface of the adhered object so that the vapor deposition material remains on the surface of the adhered object.

According to the configuration, the second heating device heats up the surface of the adhered object such that the surface of the adhered object is not less than the temperature at which the vapor deposition material becomes transformed into gaseous form. This allows gaseous vapor deposition particles to be emitted from the vapor deposition material remaining on the surface of the adhered object.

In a case where there is no interval between (i) the adherence of the vapor deposition particles to the surface of the adhered object and (ii) the emission of the vapor deposition particles, heat generated by the first heating device serves as heat that preheats the surface of the adhered object before the second heating device the surface. This allows for a considerable reduction in length of time between (a) initiation of the heating process by the second heating device and (b) emission of gaseous vapor deposition particles from a vapor deposition material remaining on the surface of the adhered object.

The adhered object is preferably made up of a plurality of heating plates.

By employing a plurality of heating plates as the adhered object, it is possible to enlarge the area of a surface to which vapor deposition particles are to adhere. This allows for an increase in the amount of vapor deposition particles to adhere at once, and therefore allows for an increase in the number of gaseous vapor deposition particles to be emitted by heating the surface of the adhered object. Hence, it is possible to significantly increase a vapor deposition rate at which vapor deposition particles are emitted from the emitting container.

A larger surface area of the adhered object thus allows a larger number of vapor deposition particles to adhere to the surface of the adhered object. Therefore, the adhered object can be (or made up of) a member(s) having large surface area.

The adhered object is preferably made up of fin-shaped members.

The adhered object is preferably a mesh-like member.

The adhered object preferably has a fractal surface.

A vapor deposition particle emitting system of the present invention includes a vapor deposition material filling device and a vapor deposition particle emitting device: said vapor deposition material filling device including a vapor deposition particle generating source for generating gaseous vapor deposition particles by heating a vapor deposition material, a filling container, connected to the vapor deposition particle generating source, which is to be filled with the gaseous vapor deposition particles, and vapor deposition particle adhering means for causing the vapor deposition particles to adhere to a surface of an adhered object that is provided in the filling container, so that a vapor deposition material remaining on the adhered object is obtained; and said vapor deposition particle emitting device including an emitting container which (i) is to contain the adhered object on which the vapor deposition material is remaining and (ii) has emission holes from which gaseous vapor deposition particles are emitted out and a heating device for heating the adhered object being contained in the emitting container so that a surface temperature of the adhered object is not less than a temperature at which the vapor deposition material becomes transformed into gaseous form.

According to the configuration, the following two devices are separately provided: (i) the device (vapor deposition material filling device) for causing a vapor deposition material to remain on the adhered object by causing vapor deposition particles to adhere to the adhered object and (ii) the device (vapor deposition particle emitting device) for emitting out gaseous vapor deposition particles generated from the vapor deposition material remaining on the adhered object. This allows a vapor deposition rate, at which the vapor deposition particles adhere to the adhered object in the vapor deposition material filling device, to be independent of a vapor deposition rate at which the vapor deposition particles are emitted from the adhered object in the vapor deposition particle emitting device.

This prevents the vapor deposition rate in the vapor deposition particle emitting device from being affected even in a case where the vapor deposition rate at which the vapor deposition particles adhere to the adhered object in the vapor deposition material filling device is lowered. In other words, it is possible to cause vapor deposition particles to adhere to the adhered object at a low vapor deposition rate in the vapor deposition material filling device. This makes it unnecessary to considerably raise a temperature of heat to be applied to the vapor deposition particle generating source in the vapor deposition material filling device.

Hence, it is unnecessary to exceedingly heat up the vapor deposition material, and it is therefore possible to prevent the vapor deposition material from deteriorating due to excessive heating.

The vapor deposition particle emitting system can include a cartridge which (i) is provided to be attachable to or detachable from the vapor deposition material filling device and (ii) contains the adhered object.

A method of the present invention for emitting vapor deposition particles includes the step of: heating a vapor deposition material up to a temperature not less than a temperature at which the vapor deposition material becomes transformed into gaseous form, the vapor deposition material remaining on a surface of an adhered object provided in an emitting container that has emission holes from which gaseous vapor deposition particles are emitted out.

According to the configuration, vapor deposition particles adhere to the surface of the adhered object. This causes heat, which has been applied to the adhered object, to easily flow through the entire vapor deposition particles. Therefore, by merely heating the adhered object so that its temperature is not less than a temperature at which the vapor deposition material becomes transformed into gaseous form, it is possible to obtain a large amount of gaseous vapor deposition particles at once. In other words, it is possible to increase a vapor deposition rate.

A larger surface area of the adhered object allows a larger amount of vapor deposition particles to adhere to the surface of the adhered object. This makes it possible to obtain even a larger amount of vapor deposition particles at once, i.e., to further increase the vapor deposition rate.

In addition, since heat applied to the adhered object can easily flow through the entire vapor deposition particles as described above, the vapor deposition material remaining on the surface of the adhered object can be sufficiently transformed into gaseous form with the use of heat at a temperature as close as possible to a vaporizing temperature of the vapor deposition material (in a case where the vapor deposition material is in liquid form) or a sublimating temperature of the vapor deposition material (in a case where the vapor deposition material is in solid form). This makes it unnecessary to excessively heat up the vapor deposition material for the purpose of increasing the vapor deposition rate, and therefore makes it possible to prevent the vapor deposition material from deteriorating due to excessive heat.

With the configuration, therefore, it is possible to increase the vapor deposition rate without excessively heating up the vapor deposition material.

A method of the present invention for emitting vapor deposition particles includes the steps of: (a) supplying vapor deposition particles, which are formed by transforming a vapor deposition material into gaseous form, into an emitting container that contains an adhered object having a surface to which the vapor deposition particles can adhere; (b), in the step (a), causing a vapor deposition material to remain on the surface of the adhered object by causing the vapor deposition particles to adhere to the surface of the adhered object through controlling a surface temperature of the adhered object so as to be less than a temperature at which the vapor deposition material become vaporized; (c) heating the vapor deposition material thus remaining on the surface of the adhered object as a result of the step (b) such that a temperature of the vapor deposition material is not less than the temperature at which to become transformed into gaseous form, so that gaseous vapor deposition particles are obtained; and (d) emitting the gaseous vapor deposition particles, which have been obtained in the step (c), from emission holes toward a vapor deposition object.

Note that a temperature, at which gaseous vapor deposition particles are generated from a vapor deposition material, is (i) a vaporizing temperature in a case where the vapor deposition material is in liquid form and (ii) a sublimating temperature in a case where the vapor deposition material is in solid form.

According to the configuration, (i) the vapor deposition particles adhere to the surface of the adhered object, which is contained in the emitting container, so that the vapor deposition material remains on the surface of the adhered object and then (ii) the vapor deposition material remaining on the adhered object are transformed into gaseous form. This allows an amount of vapor deposition material, which is to be transformed into gaseous form at once, to be increased without raising a heating temperature as much as is the case in which a vapor deposition material is transformed into gaseous form by being heated in a crucible or the like. That is, a vapor deposition rate can be increased.

A vapor deposition device of the present invention includes, as a vapor deposition source, the vapor deposition particle emitting device.

With the vapor deposition device configured as such, it is possible to increase a vapor deposition rate without excessively heating a vapor deposition material.

The vapor deposition device of the present invention preferably further includes a vapor deposition mask for forming a vapor deposition film in a pattern.

By employing the vapor deposition mask, it is possible to obtain a film in a desired pattern.

The vapor deposition device can be configured such that the vapor deposition film thus formed is an organic layer of an organic electroluminescence element. The vapor deposition device thus configured is suitable as a device for producing an organic electroluminescence element. In other words, the vapor deposition device can be a device for producing an organic electroluminescence element.

A method for producing an organic electroluminescence element, in which the vapor deposition particle emitting device of the present invention is used, includes the steps of, for example: (i) preparing a first electrode on a TFT substrate; (ii) vapor depositing, on the TFT substrate, an organic layer including at least a luminescent layer; and (iii) vapor depositing a second electrode, during at least one of the steps (i) and (ii), the vapor deposition particle emitting device being used as a vapor deposition source.

Since the vapor deposition particle emitting device of the present invention is thus used as a vapor deposition source, it is possible to increase a vapor deposition rate without excessively heating a vapor deposition material. This prevents the vapor deposition material from being wasted even in a case where the vapor deposition rate is increase, and therefore makes it possible to increase efficiency in use of the vapor deposition material.

Therefore, it is possible to reduce the cost of producing an organic electroluminescence element. As a result, it is possible to inexpensively produce an organic EL display device.

The present invention is not limited to the description of the embodiments, but can be altered in many ways by a person skilled in the art within the scope of the claims. An embodiment derived from a proper combination of technical means disclosed in different embodiments is also encompassed in the technical scope of the present invention.

### INDUSTRIAL APPLICABILITY

A vapor deposition particle emitting device and a vapor deposition device of the present invention are each suitable for a device, method, and the like for producing an organic EL display device which device, method, and the like are for use in, for example, a film formation process such as selective formation of an organic layer in production of an organic EL display device.

### REFERENCE SIGNS LIST

1 Organic EL display device
2R, 2G, 2B Pixel
10 TFT substrate
11 Insulating substrate
12 TFT
13 Interlayer insulating film
13a Contact hole
14 Wire
15 Edge cover
20 Organic EL element
21 First electrode
22 Hole injection layer/hole transfer layer
23R Luminescent layer
23R, 23G, 23B Luminescent layer
24 Electron transfer layer
25 Electron injection layer
26 Second electrode
30 Adhesive layer
40 Sealing substrate
91 Vapor deposition particle
100 Heating plate unit
101 Heating plate
101a Surface
110 Nozzle section (emitting container)
110a Housing outer circumferential surface
111 Emission hole
120 Vapor deposition particle generating section
121 Container
122 Heater
124 Vapor deposition material
130 Introduction tube
131 Restriction plate
140 Valve
150 Cooling device
151 Heat exchange member
160 Heating device
161 Heating device
162 First heating device
163 Second heating device
170 Heating container
171 Emission hole
180 Vapor deposition material filling device
200 Film formation substrate
201 Film formation surface
300 Vapor deposition mask
301 Opening
500 Vacuum chamber
501 Vapor deposition particle emitting device
502 Vapor deposition particle emitting device
503 Vapor deposition particle emitting device
600 Vapor deposition source unit
700 Vapor deposition source

1. A vapor deposition particle emitting device comprising:
a vapor deposition particle generating source for generating gaseous vapor deposition particles by heating a vapor deposition material;
an emitting container, connected to the vapor deposition particle generating source, which has emission holes for emitting out gaseous vapor deposition particles;
an adhered object, provided in the emitting container, to which vapor deposition particles adhere so that the vapor deposition material remains on a surface of the adhered object; and
a surface temperature controlling device for controlling a surface temperature of the adhered object so as to be less or not less than a temperature at which the vapor deposition material becomes transformed into gaseous form.

2. The vapor deposition particle emitting device as set forth in claim 1, wherein the surface temperature controlling device includes:
a cooling device for cooling the adhered object so that the surface temperature of the adhered object is less than the temperature at which the vapor deposition material becomes transformed into gaseous form; and
a heating device for heating the adhered object so that the surface temperature of the adhered object is not less than the temperature at which the vapor deposition material becomes transformed into gaseous form.

3. The vapor deposition particle emitting device as set forth in claim 1, wherein the surface temperature controlling device includes:
a first heating device for heating the adhered object to such an extent that the surface temperature of the adhered object is the temperature at which the vapor deposition material becomes transformed into gaseous form; and
a second heating device for heating the adhered object so that the surface temperature of the adhered object is not less than the temperature at which the vapor deposition material becomes transformed into gaseous form.

4. A vapor deposition particle emitting device comprising:
an emitting container having emission holes from which gaseous vapor deposition particles are emitted out;
an adhered object, provided in the emitting container, to which vapor deposition particles adhere so that a vapor deposition material remains on a surface of the adhered object; and
a heating device for heating the vapor deposition material, which is remaining on the surface of the adhered object, so that a temperature of the vapor deposition material is not less than a temperature at which the vapor deposition material becomes transformed into gaseous form.

5. The vapor deposition particle emitting device as set forth in claim 4, wherein the adhered object is provided to be attachable to or detachable from the emitting container.

6. The vapor deposition particle emitting device as set forth in claim 1, wherein the adhered object is made up of a plurality of heating plates.

7. The vapor deposition particle emitting device as set forth in claim 1, wherein the adhered object is a fin-shaped member.

8. The vapor deposition particle emitting device as set forth in claim 1, wherein the adhered object is a mesh-like member.

9. The vapor deposition particle emitting device as set forth in claim 1, wherein the adhered object has a fractal surface.

10. A vapor deposition particle emitting system comprising a vapor deposition material filling device and a vapor deposition particle emitting device:
said vapor deposition material filling device including
a vapor deposition particle generating source for generating gaseous vapor deposition particles by heating a vapor deposition material,
a filling container, connected to the vapor deposition particle generating source, which is to be filled with the gaseous vapor deposition particles, and
vapor deposition particle adhering means for causing the vapor deposition particles to adhere to a surface of an adhered object that is provided in the filling container, so that a vapor deposition material remaining on the adhered object is obtained; and
said vapor deposition particle emitting device including
an emitting container which (i) is to contain the adhered object on which the vapor deposition material is remaining and (ii) has emission holes from which gaseous vapor deposition particles are emitted out and
a heating device for heating the adhered object being contained in the emitting container so that a surface temperature of the adhered object is not less than a temperature at which the vapor deposition material becomes transformed into gaseous form.

11. A cartridge, which (i) is provided to be attachable to or detachable from the vapor deposition material filling device as set forth in claim 10 and (ii) contains the adhered object.

12. (canceled)

13. (canceled)

14. A vapor deposition device comprising, as a vapor deposition source, a vapor deposition particle emitting device as set forth in claim 1.

15. A vapor deposition device as set forth in claim 14, further comprising a vapor deposition mask for forming a vapor deposition film in a pattern.

16. The vapor deposition device as set forth in claim 15, wherein the vapor deposition film thus formed is an organic layer of an organic electroluminescence element.

17. The vapor deposition particle emitting device as set forth in claim 4, wherein the adhered object is made up of a plurality of heating plates.

18. The vapor deposition particle emitting device as set forth in claim 4, wherein the adhered object is a fin-shaped member.

19. The vapor deposition particle emitting device as set forth in claim 4, wherein the adhered object is a mesh-like member.

20. The vapor deposition particle emitting device as set forth in claim 4, wherein the adhered object has a fractal surface.
